(19) United States
(12) Patent Application Publication
(10) Pub. No.: US 2008/0029152 A1
(43) Pub. Date: Feb. 7, 2008

(54) Laser scribing apparatus, systems, and methods

(76) Inventors: Erel Milshtein, Cupertino, CA (US); Benyamin Buller, Cupertino, CA (US)

Correspondence Address: JONES DAY, 222 EAST 41ST ST, NEW YORK, NY, 10017, US

(21) Appl. No.: 11/499,608

(22) Filed: Aug. 4, 2006

(51) Int. Cl. H01L 31/00

(52) U.S. Cl. 136/252

(57) ABSTRACT

Apparatus, systems, and methods for forming a photovoltaic cell from a common layer on a substrate are provided. A first pass is made with a first laser beam over an area on the common layer. The first pass forms a groove in the common layer. The first pass forms within the common layer a first edge and a second edge. The first edge is separated from the second edge by the groove. The groove provides a first level of electrical isolation between the first edge and the second edge. A second pass is made with a second laser beam over approximately the same area on the common layer. The second pass provides a second level of electrical isolation between the first edge and the second edge. The second level of electrical isolation is greater than the first level of electrical isolation.

### 1. FIELD OF THE APPLICATION

This application relates to using laser scribing techniques.

### 2. BACKGROUND OF THE APPLICATION

Solar cells are typically fabricated as separate physical entities with light gathering surface areas on the order of 4-6 cm² or larger. For this reason, it is standard practice for power generating applications to mount the cells in a flat array on a supporting substrate or panel so that their light gathering surfaces provide an approximation of a single large light gathering surface. Also, since each cell itself generates only a small amount of power, the required voltage and/or current is realized by interconnecting the cells of the array in a series and/or parallel matrix.

A conventional prior art solar cell structure is shown in FIG. 1. Because of the large range in the thickness of the different layers, they are depicted schematically. Moreover, FIG. 1 is highly schematic so that it represents the features of both thick-film solar cells and thin-film solar cells. In general, solar cells that use an indirect band gap material to absorb light are typically configured as thick-film solar cells because a thick absorber layer is required to absorb a sufficient amount of light. Solar cells that use a direct band gap material to absorb light are typically configured as thin-film solar cells because only a thin layer of the direct band-gap material is needed to absorb a sufficient amount of light.

The arrows at the top of FIG. 1 show the source of direct solar illumination on the cell. Layer 102 is the substrate. Glass or metal is a common substrate. In thin-film solar cells, substrate 102 can be-a polymer-based backing, metal, or glass. In some instances, there is an encapsulation layer (not shown) coating substrate 102. Layer 104 is the back electrical contact for the solar cell.

Layer 106 is the semiconductor absorber layer. Back electrode 104 makes ohmic contact with absorber layer 106. In many but not all cases, absorber layer 106 is a p-type semiconductor. Absorber layer 106 is thick enough to absorb light. Layer 108 is the semiconductor junction partner-that, together with semiconductor absorber layer 106, completes the formation of a p-n junction. A p-n junction is a common type of junction found in solar cells. In p-n junction based solar cells, when semiconductor absorber layer 106 is a p-type doped material, junction partner 108 is an n-type doped material. Conversely, when semiconductor absorber layer 106 is an n-type doped material, junction partner 108 is a p-type doped material. Generally, junction partner 108 is much thinner than absorber layer 106. For example, in some instances junction partner 108 has a thickness of about 0.05 microns. Junction partner 108 is highly transparent to solar radiation. Junction partner 108 is also known as the window layer, since it lets the light pass down to absorber layer 106.

In a typical thick-film solar cell, absorber layer 106 and window layer 108 can be made from the same semiconductor material but have different carrier types (dopants) and/or carrier concentrations in order to give the two layers their distinct p-type and n-type properties. In thin-film solar cells in which copper-indium-gallium-diselenide (CIGS) is the absorber layer 106, the use of CdS to form junction partner 108 has resulted in high efficiency cells. Other materials that can be used for junction partner 108 include, but are not limited to, In₂Se₃, In₂S₃, ZnS, ZnSe, CdInS, CdZnS, ZnIn₂Se₄, Zn₁₋ₓMgₓO, CdS, SnO₂, ZnO, ZrO₂ and doped ZnO.

Layer 110 is the transparent conductor, which completes the functioning cell. Transparent conductor 110 is used to draw current away from the junction since junction partner 108 is generally too resistive to serve this function. As such, transparent conductor 110 is typically highly conductive and transparent to light. Transparent conductor 110 can in fact be a comb-like structure of metal printed onto layer 108 rather than forming a discrete layer. Transparent conductor 110 is typically a transparent conductive oxide (TCO) such as doped zinc oxide (e.g., aluminum doped zinc oxide, gallium doped zinc oxide, boron doped zinc oxide), indium-tin-oxide (ITO), tin oxide (SnO₂), or indium-zinc oxide. However, even when a TCO layer is present, a bus bar network 120 is typically needed in conventional solar cells to draw off current since the TCO has too much resistance to efficiently perform this function in larger solar cells. Network 120 shortens the distance charge carriers must move in the TCO layer in order to reach the metal contact, thereby reducing resistive losses. The metal bus bars, also termed grid lines, can be made of any reasonably conductive metal such as, for example, silver, steel or aluminum. In the design of network 120, there is design a trade off between thicker grid lines that are more electrically conductive but block more light, and thin grid lines that are less electrically conductive but block less light. The metal bars are preferably configured in a comb-like arrangement to permit light rays through transparent conductor 110. Bus bar network layer 120 and transparent conductor 110, combined, act as a single metallurgical unit, functionally interfacing with a first ohmic contact to form a current collection circuit. In U.S. Pat. No. 6,548,751 to Sverdrup et al., hereby incorporated by reference herein in its entirety, a combined silver bus bar network and indium-tin-oxide layer function as a single, transparent ITO/Ag layer.

Layer 112 is an antireflective coating that can allow a significant amount of extra light into the cell. Depending on the intended use of the cell, it might be deposited directly on the top conductor as illustrated in FIG. 1. Alternatively or additionally, antireflective coating 112 may be deposited on a separate cover glass or other type of transparent covering that overlays transparent conductor 110. Ideally, the antireflective coating reduces the reflection of the cell to very near zero over the spectral region in which photoelectric absorption occurs, and at the same time increases the reflection in the other spectral regions to reduce heating. U.S. Pat. No. 6,107,564 to Aguilera et al., hereby incorporated by reference herein in its entirety, describes representative antireflective coatings.

Solar cells typically produce only a small voltage. For example, silicon based solar cells produce a voltage of about 0.6 volts (V). Thus, solar cells are interconnected in series or parallel in order to achieve greater voltages. When connected in series, voltages of individual cells add together while current remains the same. When compared to analogous solar cells arrange in parallel, solar cells arranged in series reduce the amount of current flow through such cells, thereby improving efficiency. As illustrated in FIG. 1, the arrangement of solar cells in series is accomplished, for example, using interconnects 116. In general, an interconnect 116 places the first electrode of one solar cell in electrical communication with the counter-electrode of an adjoining solar cell.

Various fabrication techniques (e.g., mechanical and laser scribing) are used to segment solar cells into individual photovoltaic cells and to generate high output voltage through integration of such segmented photovoltaic cells. Grooves that separate individual photovoltaic cells typically have low series resistance and high shunt resistance to facilitate integration. Such grooves are made as small as possible in order to minimize dead area and optimize material usage. Relative to mechanical scribing, laser scribing is more precise and suitable for more types of material. This is because hard or brittle materials often break or shatter during mechanical scribing, making it difficult to create narrow grooves between photovoltaic cells.

During laser scribing, radiation energy is absorbed by the lattice of the one or more layers constituting the solar cell, resulting in changes in the morphological and physical properties in a heat-affected-zone (HAZ) of the material. As a result, the material undergoes melting, sublimation, evaporation and/or solidification in the HAZ. The nature of the thermal induced changes in the HAZ is dependent upon the specific properties of the incident laser beam, including the laser beam wavelength, pulse duration, and power density. The nature of the thermal induced changes in the HAZ is also dependent upon the nature of the material constituting the HAZ, such as its heat capacity, melting point, boiling point, etc.

Despite the advantages of laser scribing, problems are known to occur within the HAZ. For some materials, conductive ridges or “collars” are left along the edges of the scribed line or groove within the HAZ. In addition, melted residues at the bottom of a scribed groove may change to a conductive phase upon heating. This can introduce electrical shorts, poor isolation between photovoltaic cells, and low shunt resistance to reduce voltage integration. For more discussion of such laser scribing drawbacks, see Compaan et al., 2000, “Laser Scribing of Polycrystalline Thin Films,” Optics and Lasers in Engineering 34: 15-45; Wennerberg et al., 2001, “Design of Grided Cu(In,Ga)Se₂ Thin-film PV Modules,” Solar Energy Materials & Solar Cells 67: 59-65; and Birkmire and Eser, 1997, “Polycrystalline Thin File Solar Cells: Present Status and Future Potential,” Annu. Rev. Mater. Sci. 17: 625-653; each of which is hereby incorporated by reference herein in its entirety. As used herein, the terms laser scribing, etching, laser ablation, and ablation are used interchangeably.

During a laser scribing process, shunts may be created in a layer in a solar cell (e.g., layer 104, 106, 108, or 110 in FIG. 1). FIG. 1B is an electron micrograph that illustrates one type of a shunt. Layer 170 is disposed on substrate 180. Energy from a laser beam melts and evaporates part of layer 170 to form groove 176 within the HAZ of layer 170. Residue 172, from the HAZ of layer 170, is scattered in groove 176. Residue 172 may vary in size, as illustrated in both FIGS. 1B and 1C. Furthermore, even though layer 170 may be a semiconductor, residue 172, as a result of the laser heating and annealing, may have conductive properties. Thus, it is possible for residue 172 to cause shunts, such as shunt 172-3 of FIG. 1C. When groove 176 is densely populated with residue 172, as shown in FIG. 1B, the entire groove may be rendered conductive and thereby allow current to flow across the groove (e.g., from side 176-1 to side 176-2 in FIG. 1C or vice versa). Such artifacts defeat the advantages of generating high voltage solar cell assemblies through, for example, monolithic integration of photovoltaic cells. Therefore, what is needed in the art are systems and methods for creating electrically isolating grooves.

Discussion or citation of a reference herein will not be construed as an admission that such reference is prior art to the present application.

### 3. BRIEF DESCRIPTION OF THE DRAWINGS

FIG. 1A illustrates interconnected solar cells in accordance with the prior art.

FIG. 1B illustrates a laser scribed surface in accordance with the prior art.

FIG. 1C illustrates a laser scribed surface in accordance with the prior art.

FIG. 2A illustrates a photovoltaic element with a transparent tubular casing in accordance with embodiments of the present application.

FIG. 2B illustrates a cross-sectional view of an elongated solar cell in a transparent tubular casing in accordance with embodiments of the present application.

FIG. 2C illustrates a cross-sectional view of an elongated solar cell in a transparent tubular casing in accordance with embodiments of the present application.

FIG. 2D illustrates a photovoltaic element with a transparent tubular casing in accordance with embodiments of the present application.

FIG. 2E illustrates a cross-sectional view of an elongated solar cell comprising a plurality of photovoltaic cells in accordance with embodiments of the present application.

FIGS. 3A-3M illustrate processing steps for forming a monolithically integrated solar cell unit in accordance with embodiments of the present application.

FIGS. 4A & 4B illustrate exemplary embodiments in accordance with the present application.

FIGS. 4C & 4D illustrate exemplary embodiments in accordance with embodiments of the present application.

FIGS. 4E & 4F illustrate exemplary embodiments, in accordance with embodiments of the present application.

FIGS. 5A-5D illustrate semiconductor junctions in accordance with embodiments of the present application.

FIGS. 6A-5D illustrate fabrication steps in accordance with embodiments of the present application.

Like reference numerals refer to corresponding parts throughout the several views of the drawings. Dimensions are not drawn to scale.

### 4. DETAILED DESCRIPTION

Disclosed herein are apparatus, systems, and methods for laser scribing. Such apparatus, systems, and methods can be used for a wide range of applications such as for manufacturing solar cells that convert solar energy. When such apparatus, systems, and methods are used to construct solar cells, they have the advantage of reducing or eliminating the presence shunts in such solar cells. Solar cells constructed by the disclosed apparatus, systems, and methods may have elongated cylindrical or planar shapes. More generally, the present invention can be used to facilitate a broad array of micromachining techniques including microchip fabrication. Micromachining (also termed microfabrication, micromanufacturing, micro electromechanical systems) refers to the fabrication of devices with at least some of their dimensions in the micrometer range. See, for example, Madou, 2002, Fundamentals of Microfabrication, Second Edition, CRC Press LLC, Boca Raton, Fla., which is hereby incorporated by reference herein in its entirety for its teachings on microfabrication. Microchip fabrication is disclosed in Van Zant, 2000, Microchip Fabrication, Fourth Edition, McGraw-Hill, New York.

One aspect of the application discloses methods for constructing a solar cell or other device that comprise a plurality of layers. The method comprises making a primary laser beam pass and one or more secondary laser beam passes through an area on at least one common layer that is ultimately patterned to form a solar cell comprising a plurality of photovoltaic units. The laser beam passes melt at least a portion of the layer underlying the area and collectively create a scribed electrically isolating groove. In some embodiments, an electrically isolating groove is created after three or more laser beam passes, five or more laser beam passes, ten or more laser beam passes, fifteen or more laser beam passes, or twenty or more laser beam passes. In some embodiments, the scribed groove penetrates at least one layer of the solar cell. In some embodiments, the scribed groove does not penetrate one layer of the solar cell. In some embodiments, the length of the scribed groove is a portion of a length of one layer of the solar cell or a portion of a width of one layer of the solar cell. In some embodiments, the length of the scribed groove is a portion of a circumference of one layer in a solar cell.

In some embodiments, a laser beam is generated by a pulsed laser. In other embodiments, a laser beam irradiates continuous energy. In some embodiments, a pulsed laser used in the present application has a pulse frequency in the range of 0.1 kilohertz (kHz) to 1000 kHz. In some embodiments, a pulsed laser has a pulse duration in the range of 10 nanoseconds to 3.0×10⁷ nanoseconds. In some embodiments, a primary laser beam pass (first pass) and one or more secondary laser beam passes (second pass) are made by a laser beam generated by a gas, liquid, or solid laser. Exemplary gas lasers include, but are not limited to, He—Ne, He—Cd, Cu vapor, Ag vapor, HeAg, NeCu, CO₂, N₂, HF-DF, far infrared, F₂, XeF, XeCl, ArF, KrCl, or KrF lasers. Exemplary liquid lasers include dye lasers. Exemplary solid lasers include, but are not limited to, ruby, Nd:YAG, Nd:glass, color center, alexandrite, Ti:sapphire, Yb:KGW, Yb:KYW, Yb:SYS, Yb:BOYS, Yb:CaF₂, semiconductor, glass or optical fiber hosted lasers, vertical cavity surface-emitting laser (VCSEL), or laser diode lasers. In some embodiments, a laser beam is generated by an x-ray, infrared, ultraviolet, or free electron transfer laser. In some embodiments, a primary laser beam pass (first pass) and one or more secondary laser beam passes (collectively, a second pass) are made by more than one laser beam.

In some embodiments, a laser beam has a wavelength in the range of 10 nanometers to 1×10⁶ nanometers. In some embodiments, a dose of radiant energy containing radiant energy in a range from 0.01 Joules per square centimeters (J/cm²) to 50.0 J/cm² is delivered to a designated area by a laser beam. In some embodiments, a laser beam comprises more than one laser beam component. These components, for example, can be visually separated from each other.

In some embodiments, a primary laser beam pass and one or more secondary laser beam passes are created by moving the laser beam, the scribed surface, or both with respect to each other. In some embodiments, such movements may be translational movements and/or rotational movements. In some embodiments, the laser beam or scribed surface move in a periodic motion in one or more orthogonal translational dimensions with respect to each other. In some embodiments, the laser beam or scribed surface move in a non-periodic motion in one or more dimensions with respect to each other.

In some embodiments, the scribed area is on a back-electrode, semiconductor junction, or counter-electrode. In some embodiments, the semiconductor junction comprises a plurality of layers such as an absorber layer and a junction partner layer. In some embodiments, the junction partner layer is circumferentially disposed on the absorber layer and the absorber layer is made of a material such as copper-indium-gallium-diselenide while the junction partner layer is In₂Se₃, In₂S₃, ZnS, ZnSe, CdInS, CdZnS, ZnIn₂Se₄, Zn₁₋ₓMgₓO, CdS, SnO₂, ZnO, ZrO₂, doped ZnO, or a combination thereof.

Another aspect of the application comprises a solar cell unit having a substrate and a plurality of photovoltaic cells. The plurality of photovoltaic cells is linearly arranged on the substrate. The plurality of photovoltaic cells comprises a first photovoltaic cell and a second photovoltaic cell. Each photovoltaic cell in the plurality of photovoltaic cells comprises (i) a back-electrode circumferentially disposed on the substrate, (ii) a semiconductor junction circumferentially disposed on the back-electrode, (iii) a transparent conductor circumferentially disposed on the semiconductor junction. The transparent conductor of the first photovoltaic cell in the plurality of photovoltaic cells is in serial electrical communication with the back-electrode of the second photovoltaic cell in the plurality of photovoltaic cells. In this aspect of the application, the back-electrode, semiconductor junction, and/or transparent conductor is patterned by (i) making a primary laser beam pass through an area on the back-electrode, semiconductor junction, and/or transparent conductor thereby creating a heat affected zone; and (ii) making one or more secondary laser beam passes through the heat affected zone thereby removing all or a portion of the heat affected zone such that a first side of a groove thereby formed is electrically isolated from a second side of the groove. In some embodiments, these steps are accomplished with a laser beam that illuminates the area with a predetermined shape having (i) a first edge with a first width and (ii) having a second edge with a second width that is larger than the first width. Yet another aspect of the present application further provides a solar cell manufactured by the disclosed apparatus, systems and methods, encased in a transparent tubular casing.

### 4.1 System Overview

The present application provides systems, methods and apparatus for creating electrically isolating grooves, therefore eliminating voltage reduction caused by low-resistance shunts across such grooves. The systems, methods, and apparatus are designed to provide appropriate optical energy to an area that is already affected by previous optical exposure, in order to remove residual material.

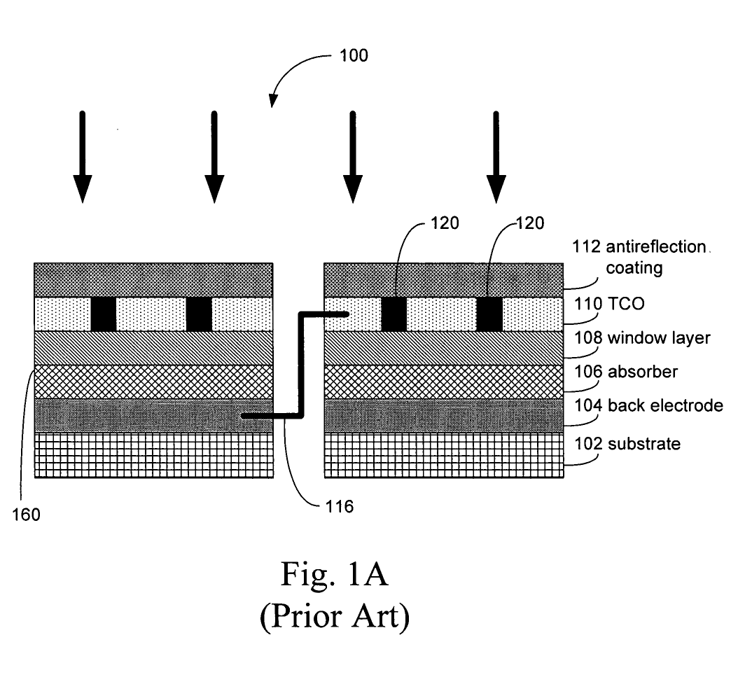

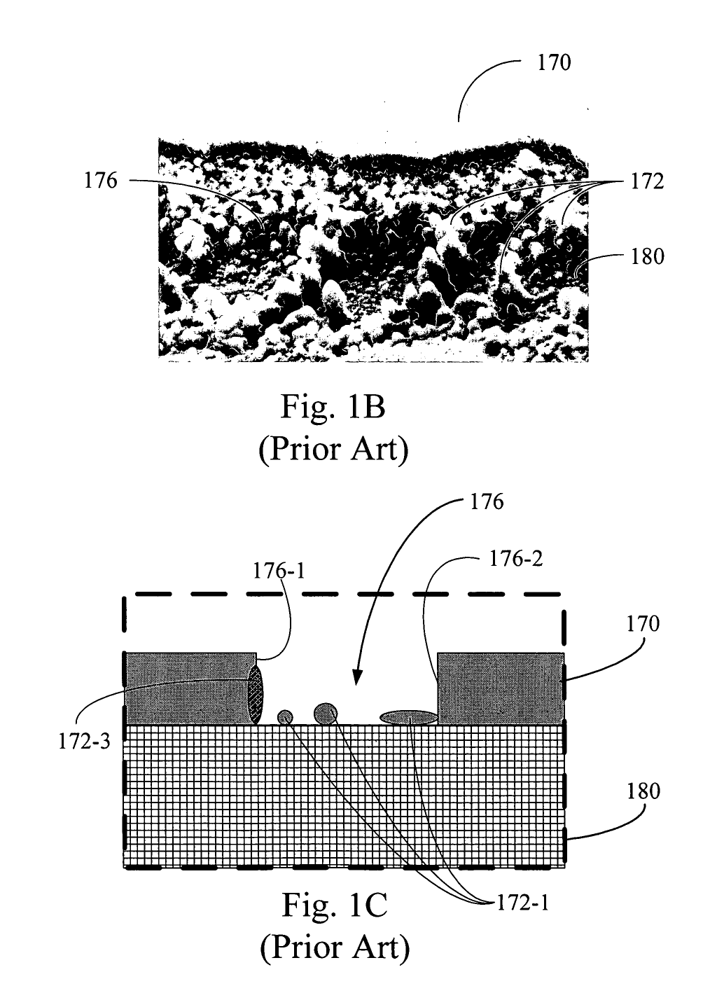

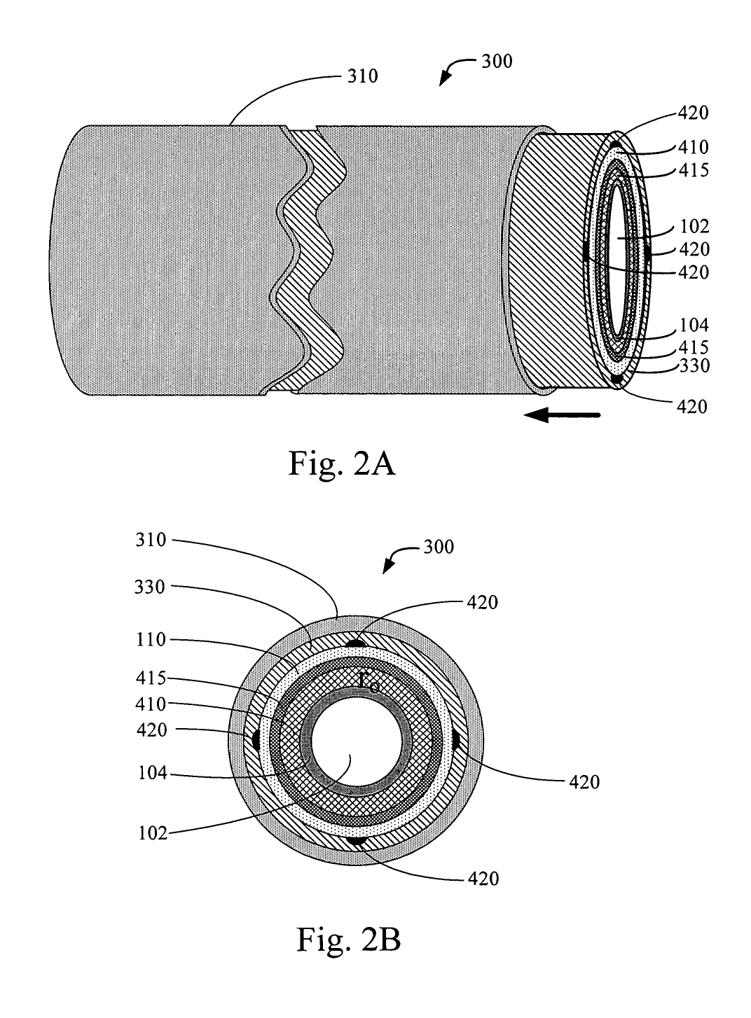

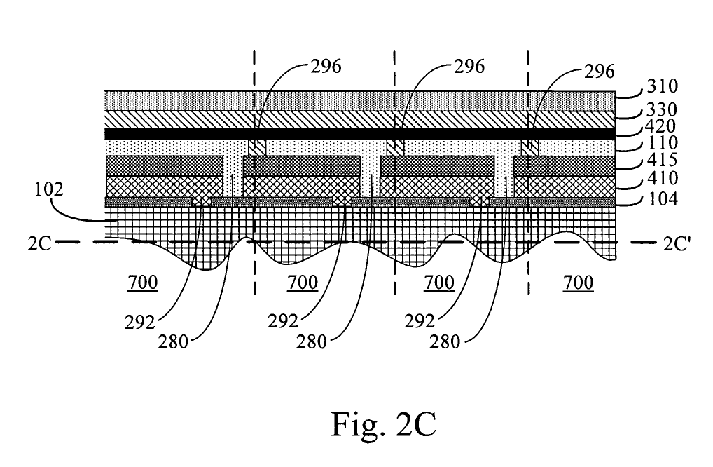

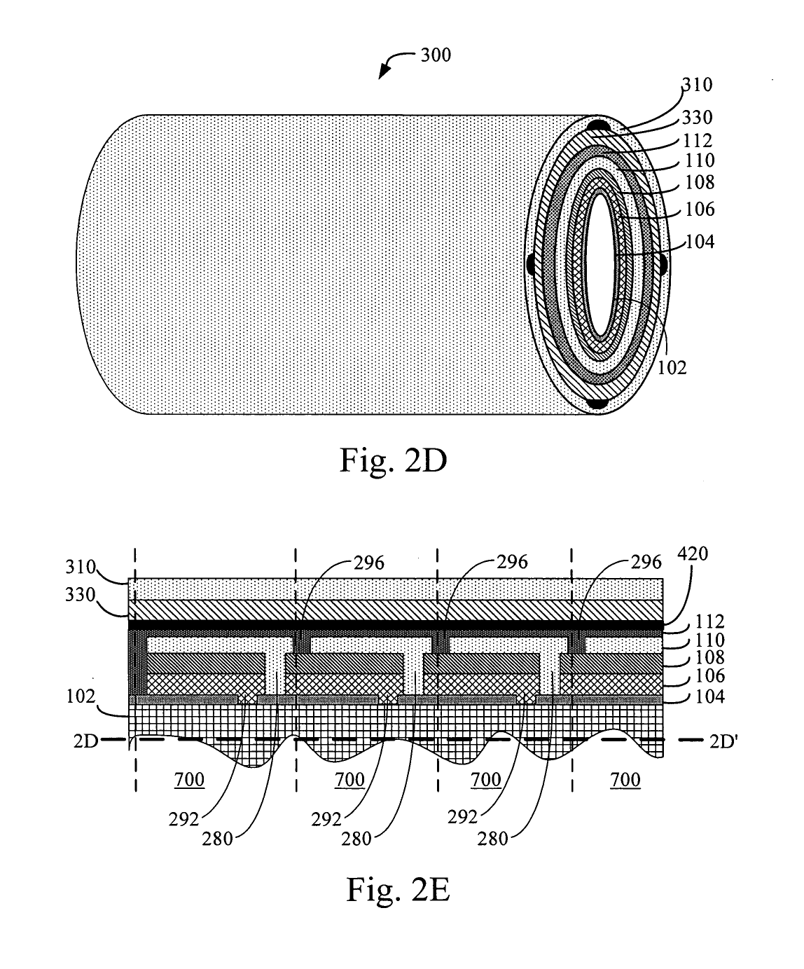

Some embodiments in accordance with the present application result in the fabrication of cylindrical solar cell units 300 that are illustrated in FIG. 2. Some embodiments in accordance with present application result in the fabrication of flat panel solar cells such as those illustrated in FIG. 1A. What follows is a description of some of the components found in solar cells that may be patterned using the apparatus, systems and methods disclosed herein. One of the many purposes of such patterning could be to break a solar cell up into discrete photovoltaic units that may then be serially combined in a process known as “monolithic integration.” Such monolithic integration has the advantage of reducing current carrying requirements of the solar cell. Sufficient monolithic integration, therefore, substantially reduces electrode, transparent conductor, and counter-electrode current carrying requirements, thereby minimizing material costs. The present application provides improved methods for forming the necessary grooves needed to form serially connected photovoltaic units in a solar cell.

Substrate 102. Referring, for example, to FIG. 2A, substrate 102 serves as a substrate for the solar cell. Some embodiments of the present application are on flat planar substrates 102 such as the substrate 102 illustrated in FIG. 1A and some are on cylindrical substrates or tubular substrates such as the substrate 102 illustrated in FIGS. 2A and 2B. As used here, the term cylindrical means objects having a cylindrical or approximately cylindrical shape. In some embodiments, the shape of substrate 102 is only approximately that of a cylindrical object, meaning that a cross-section taken at a right angle to the long axis of substrate 102 defines an ellipse or other closed form graph rather than a circle. As the term is used here, such approximately circular shaped objects are still considered cylindrically shaped in the present application. In fact, cylindrical objects can have irregular shapes so long as the object, taken as a whole, is roughly cylindrical. Such cylindrical shapes can be solid (e.g., a rod) or hollowed (e.g., a tube). As used here, the term tubular means objects having a tubular or approximately tubular shape. In fact, tubular objects can have irregular shapes so long as the object, taken as a whole, is roughly tubular.

In some embodiments, substrate 102 is made of a plastic, metal, metal alloy, glass, glass fibers, glass tubing, or glass tubing. In some embodiments, substrate 102 is made of a urethane polymer, an acrylic polymer, a fluoropolymer, polybenzamidazole, polyimide, polytetrafluoroethylene, polyetheretherketone, polyamide-imide, glass-based phenolic, polystyrene, cross-linked polystyrene, polyester, polycarbonate, polyethylene, polyethylene, acrylonitrile-butadiene-styrene, polytetrafluoro-ethylene, polymethacrylate, nylon 6,6, cellulose acetate butyrate, cellulose acetate, rigid vinyl, plasticized vinyl, or polypropylene. In some embodiments, substrate 102 is made of aluminosilicate glass, borosilicate glass (e.g., Pyrex, Duran, Simax, etc.), dichroic glass, germanium/semiconductor glass, glass ceramic, silicate/fused silica glass, soda lime glass, quartz glass, chalcogenide/sulphide glass, fluoride glass, pyrex glass, a glass-based phenolic, cereated glass, or flint glass.

In some embodiments, substrate 102 is made of a material such as polybenzamidazole (e.g., Celazole®, available from Boedeker Plastics, Inc., Shiner, Tex.). In some embodiments, substrate 102 is made of polymide (e.g., DuPont™ Vespel®, or DuPont™ Kapton®, Wilmington, Del.). In some embodiments, substrate 102 is made of polytetrafluoroethylene (PTFE) or polyetheretherketone (PEEK), each of which is available from Boedeker Plastics, Inc. In some embodiments, substrate 102 is made of polyamide-imide (e.g., Torlon® PAI, Solvay Advanced Polymers, Alpharetta, Ga.).

In some embodiments, substrate 102 is made of a glass-based phenolic. Phenolic laminates are made by applying heat and pressure to layers of paper, canvas, linen or glass cloth impregnated with synthetic thermosetting resins. When heat and pressure are applied to the layers, a chemical reaction (polymerization) transforms the separate layers into a single laminated material with a “set” shape that cannot be softened again. Therefore, these materials are called “thermosets.” A variety of resin types and cloth materials can be used to manufacture thermoset laminates with a range of mechanical, thermal, and electrical properties. In some embodiments, substrate 102 is a phenoloic laminate having a NEMA grade of G-3, G-5, G-7, G-9, G-10 or G-11. Exemplary phenolic laminates are available from Boedeker Plastics, Inc.

In some embodiments, substrate 102 is made of polystyrene. Examples of polystyrene include general purpose polystyrene and high impact polystyrene as detailed in Marks' Standard Handbook for Mechanical Engineers, ninth edition, 1987, McGraw-Hill, Inc., p. 6-174, which is hereby incorporated by reference herein in its entirety. In still other embodiments, substrate 102 is made of cross-linked polystyrene. One example of cross-linked polystyrene is Rexolite® (C-Lec Plastics, Inc). Rexolite is a thermoset, in particular a rigid and translucent plastic produced by cross linking polystyrene with divinylbenzene.

In some embodiments, substrate 102 is a polyester wire (e.g., a Mylar® wire). Mylar® is available from DuPont Teijin Films (Wilmington, Del.). In still other embodiments, substrate 102 is made of Durastone®, which is made by using polyester, vinylester, epoxid and modified epoxy resins combined with glass fibers (Roechling Engineering Plastic Pte Ltd., Singapore).

In still other embodiments, substrate 102 is made of polycarbonate. Such polycarbonates can have varying amounts of glass fibers (e.g., 10% or more, 20% or more, 30% or more, or 40% or more) in order to adjust tensile strength, stiffness, compressive strength, as well as the thermal expansion coefficient of the material. Exemplary polycarbonates are Zelux® M and Zelux® W, which are available from Boedeker Plastics, Inc.

In some embodiments, substrate 102 is made of polyethylene. In some embodiments, substrate 102 is made of low density polyethylene (LDPE), high density polyethylene (HDPE), or ultra high molecular weight polyethylene (UHMW PE). Chemical properties of HDPE are described in Marks' Standard Handbook for Mechanical Engineers, ninth edition, 1987, McGraw-Hill, Inc., p. 6-173, which is hereby incorporated by reference herein in its entirety. In some embodiments, substrate 102 is made of acrylonitrile-butadiene-styrene, polytetrfluoro-ethylene (Teflon), polymethacrylate (lucite or plexiglass), nylon 6,6, cellulose acetate butyrate, cellulose acetate, rigid vinyl, plasticized vinyl, or polypropylene. Chemical properties of these materials are described in Marks' Standard Handbook for Mechanical Engineers, ninth edition, 1987, McGraw-Hill, Inc., pp. 6-172 through 1-175, which is hereby incorporated by reference herein in its entirety.

Additional exemplary materials that can be used to form substrate 102 are found in Modern Plastics Encyclopedia, McGraw-Hill; Reinhold Plastics Applications Series, Reinhold Roff, Fibres, Plastics and Rubbers, Butterworth; Lee and Neville, Epoxy Resins, McGraw-Hill; Bilmetyer, Textbook of Polymer Science, Interscience; Schmidt and Marlies, Principles of high polymer theory and practice, McGraw-Hill; Beadle (ed.), Plastics, Morgan-Grampiand, Ltd., 2 vols. 1970; Tobolsky and Mark (eds.), Polymer Science and Materials, Wiley, 1971; Glanville, The Plastics's Engineer's Data Book, Industrial Press, 1971; Mohr (editor and senior author), Oleesky, Shook, and Meyers, SPI Handbook of Technology and Engineering of Reinforced Plastics Composites, Van Nostrand Reinhold, 1973, each of which is hereby incorporated by reference herein in its entirety.

In some embodiments, substrate 102 is optically transparent to wavelengths that are generally absorbed by the semiconductor junction of a solar cell. In some embodiments, substrate 102 is not optically transparent.

Back-electrode 104. A back-electrode 104 is disposed on substrate 102. Back-electrode 104 serves as the first electrode in the assembly. In general, back-electrode 104 is made out of any material such that it can support the photovoltaic current generated by solar cell unit 300 with negligible resistive losses. In some embodiments, back-electrode 104 is composed of any conductive material, such as aluminum, molybdenum, tungsten, vanadium, rhodium, niobium, chromium, tantalum, titanium, steel, nickel, platinum, silver, gold, an alloy thereof (e.g. Kovar), or any combination thereof. In some embodiments, back-electrode 104 is composed of any conductive material, such as indium tin oxide, titanium nitride, tin oxide, fluorine doped tin oxide, doped zinc oxide, aluminum doped zinc oxide, gallium doped zinc oxide, boron dope zinc oxide indium-zinc oxide, a metal-carbon black-filled oxide, a graphite-carbon black-filled oxide, a carbon black-carbon black-filled oxide, a superconductive carbon black-filled oxide, an epoxy, a conductive glass, or a conductive plastic. A conductive plastic is one that, through compounding techniques, contains conductive fillers which, in turn, impart their conductive properties to the plastic. In some embodiments, the conductive plastics used in the present application to form back-electrode 104 contain fillers that form sufficient conductive current-carrying paths through the plastic matrix to support the photovoltaic current generated by solar cell unit 300 with negligible resistive losses. The plastic matrix of the conductive plastic is typically insulating, but the composite produced exhibits the conductive properties of the filler. In one embodiment, back-electrode 104 is made of molybdenum.

Semiconductor junction 410. A semiconductor junction 410 is formed on back-electrode 104. In some embodiments, semiconductor junction 410 is circumferentially disposed on back-electrode 104. Semiconductor junction 410 is any photovoltaic homojunction, heterojunction, heteroface junction, buried homojunction, p-i-n junction or a tandem junction having an absorber layer that is a direct band-gap absorber (e.g., crystalline silicon) or an indirect band-gap absorber (e.g., amorphous silicon). Such junctions are described in Chapter 1 of Bube, Photovoltaic Materials, 1998, Imperial College Press, London, as well as Lugue and Hegedus, 2003, Handbook of Photovoltaic Science and Engineering, John Wiley & Sons, Ltd., West Sussex, England, each of which is hereby incorporated by reference herein in its entirety. Details of exemplary types of semiconductors junctions 410 in accordance with the present application are disclosed in Section 4.3, below. In addition to the exemplary junctions disclosed in Section 4.3, below, junctions 410 can be multijunctions in which light traverses into the core of junction 410 through multiple junctions that, preferably, have successfully smaller band gaps. In some embodiments, semiconductor junction 410 includes a copper-indium-gallium-diselenide (CIGS) absorber layer.

Optional intrinsic layer 415. Optionally, there is a thin intrinsic layer (i-layer) 415 disposed on semiconductor junction 410. In some embodiments, layer 415 is circumferentially disposed on semiconductor junction 410. The i-layer 415 can be formed using, for example, any undoped transparent oxide including, but not limited to, zinc oxide, metal oxide, or any transparent material that is highly insulating. In some embodiments, i-layer 415 is highly pure zinc oxide.

Transparent conductor 110. In some embodiments, transparent conductor 110 is disposed on the semiconductor junction layer 410 thereby completing the circuit. In some embodiments where substrate 102 is cylindrical or tubular, a transparent conductor is circumferentially disposed on an underlying layer. As noted above, in some embodiments, a thin i-layer 415 is disposed on semiconductor junction 410. In such embodiments, transparent conductor 110 is disposed on i-layer 415.

In some embodiments, transparent conductor 110 is made of tin oxide SnOₓ (with or without fluorine doping), indium-tin oxide (ITO), doped zinc oxide (e.g., aluminum doped zinc oxide, gallium doped zinc oxide, boron dope zinc oxide), indium-zinc oxide or any combination thereof. In some embodiments, transparent conductor 110 is either p-doped or n-doped. For example, in embodiments where the outer layer of junction 410 is p-doped, transparent conductor 110 can be p-doped. Likewise, in embodiments where the outer layer of junction 410 is n-doped, transparent conductor 110 can be n-doped. In general, transparent conductor 110 is preferably made of a material that has very low resistance, suitable optical transmission properties (e.g., greater than 90%), and a deposition temperature that will not damage underlying layers of semiconductor junction 410 and/or optional i-layer 415.

In some embodiments, the transparent conductor is made of carbon nanotubes. Carbon nanotubes are commercially available, for example from Eikos (Franklin, Mass.) and are described in U.S. Pat. No. 6,988,925, which is hereby incorporated by reference herein in its entirety. In some embodiments, transparent conductor 110 is an electrically conductive polymer material such as a conductive polytiophene, a conductive polyaniline, a conductive polypyrrole, a PSS-doped PEDOT (e.g., Bayrton), or a derivative of any of the foregoing.

In some embodiments, transparent conductor 110 comprises more than one layer, including a first layer comprising tin oxide SnOₓ (with or without fluorine doping), indium-tin oxide (ITO), indium-zinc oxide, doped zinc oxide (e.g., aluminum doped zinc oxide, gallium doped zinc oxide, boron dope zinc oxide) or a combination thereof and a second layer comprising a conductive polytiophene, a conductive polyaniline, a conductive polypyrrole, a PSS-doped PEDOT (e.g., Bayrton), or a derivative of any of the foregoing. Additional suitable materials that can be used to form the transparent conductor are disclosed in United States Patent publication 2004/0187917A1 to Pichler, which is hereby incorporated by reference herein in its entirety.

Optional counter-electrodes 420. In some embodiments, counter-electrodes or leads 420 are disposed on transparent conductor 110 in order to facilitate electrical current flow. In some embodiments in which substrate 102 is cylindrical or tubular shaped, counter-electrodes 420 can be thin strips of electrically conducting material that run lengthwise along the long axis (cylindrical axis) of the cylindrically shaped solar cell, as depicted in FIG. 2A. In some embodiments, optional electrode strips 420 are positioned at spaced intervals on the surface of transparent conductor 110. For instance, in FIG. 2B, counter-electrode strips 420 run parallel to each other and are spaced out at ninety degree intervals along the cylindrical axis of the solar cell. In some embodiments, counter-electrodes 420 have a radial spacing arrangement in which strips are spaced out at five degree, ten degree, fifteen degree, twenty degree, thirty degree, forty degree, fifty degree, sixty degree, ninety degree or 180 degree intervals on the surface of transparent conductor 110. In some embodiments, there is a single counter-electrode 420 on the surface of transparent conductor 110. In some embodiments, there is no counter-electrode 420 on the surface of transparent conductor 110. In some embodiments, there is two, three, four, five, six, seven, eight, nine, ten, eleven, twelve, fifteen or more, or thirty or more counter-electrodes 420 on transparent conductor 110, all running parallel, or near parallel, to each down an axis of the solar cell. In some embodiments counter-electrodes 420 are evenly spaced about the circumference of transparent conductor 110, for example, as depicted in FIG. 2B. In alternative embodiments, counter-electrodes 420 are not evenly spaced about the circumference of transparent conductor 110. In some embodiments, counter-electrodes 420 are only on one face of the solar cell. Elements 102, 104, 410, 415 (optional), and 110 of FIG. 2B collectively comprise solar cell 402 of FIG. 2A.

In some embodiments, counter-electrodes 420 are made of conductive epoxy, conductive ink, copper or an alloy thereof, aluminum or an alloy thereof, nickel or an alloy thereof, silver or an alloy thereof, gold or an alloy thereof, conductive glue, or a conductive plastic. In some embodiments, counter-electrodes 420 are interconnected to each other by grid lines. These grid lines can be thicker than, thinner than, or the same width as counter-electrodes 420. These grid lines can be made of the same or different electrically material as counter-electrodes 420.

In some embodiments, counter-electrodes 420 are deposited on transparent conductor 110 using ink jet printing. Examples of conductive ink that can be used for such electrodes include but are not limited to silver loaded or nickel loaded conductive ink. In some embodiments epoxies as well as anisotropic conductive adhesives can be used to construct counter-electrodes 420. In typical embodiments, such inks or epoxies are thermally cured in order to form counter-electrodes 420.

Optional filler layer 330. In some embodiments, as depicted for example in FIG. 2B, a filler layer 330 of sealant such as ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, and/or a urethane is coated over transparent conductor 110 to seal out air and, optionally, to provide complementary fitting to a transparent tubular casing 310. In some embodiments, filler layer 330 is a Q-type silicone, a silsequioxane, a D-type silicon, or an M-type silicon. However, in some embodiments, optional filler layer 330 is not needed even when one or more electrode strips 420 are present. In some embodiments filler layer 330 is laced with a desiccant such as calcium oxide or barium oxide.

Transparent tubular casing 310. In embodiments in which substrate 102 is cylindrical or tubular, transparent tubular casing 310 is optionally circumferentially disposed on the outermost layer of the photovoltaic cell and/or solar cell (e.g., transparent conductor 110 and/or optional filler layer 330). In some embodiments, tubular casing 310 is made of plastic or glass. Methods, such as heat shrinking, injection molding, or vacuum loading, can be used to construct transparent tubular casing 310 such that oxygen and water is excluded from the system.

In some embodiments, transparent tubular casing 310 is made of a urethane polymer, an acrylic polymer, polymethylmethacrylate (PMMA), a fluoropolymer, silicone, poly-dimethyl siloxane (PDMS), silicone gel, epoxy, ethylene vinyl acetate (EVA), perfluoroalkoxy fluorocarbon (PFA), nylon/polyamide, cross-linked polyethylene (PEX), polyolefin, polypropylene (PP), polyethylene terephtalate glycol (PETG), polytetrafluoroethylene (PTFE), thermoplastic copolymer (for example, ETFE®, which is a derived from the polymerization of ethylene and tetrafluoroethylene: TEFLON® monomers), polyurethane/urethane, polyvinyl chloride (PVC), polyvinylidene fluoride (PVDF), Tygon®, vinyl, Viton®, or any combination or variation thereof.

In some embodiments, transparent tubular casing 310 comprises a plurality of transparent tubular casing layers. In some embodiments, each transparent tubular casing is composed of a different material. For example, in some embodiments, transparent tubular casing 310 comprises a first transparent tubular casing layer and a second transparent tubular casing layer. Depending on the exact configuration of the solar cell, the first transparent tubular casing layer is disposed on the transparent conductor 110, optional filler layer 330 or the water resistant layer. The second transparent tubular casing layer is disposed on the first transparent tubular casing layer.

In some embodiments, each transparent tubular casing layer has different properties. In one example, the outer transparent tubular casing layer has excellent UV shielding properties whereas the inner transparent tubular casing layer has good water proofing characteristics. Moreover, the use of multiple transparent tubular casing layers can be used to reduce costs and/or improve the overall properties of transparent tubular casing 310. For example, one transparent tubular casing layer may be made of an expensive material that has a desired physical property. By using one or more additional transparent tubular casing layers, the thickness of the expensive transparent tubular casing layer may be reduced, thereby achieving a savings in material costs. In another example, one transparent tubular casing layer may have excellent optical properties (e.g., index of refraction, etc.) but be very heavy. By using one or more additional transparent tubular casing layers, the thickness of the heavy transparent tubular casing layer may be reduced, thereby reducing the overall weight of transparent tubular casing 310. In some embodiments, only one end of the elongated solar cell is exposed by transparent tubular casing 310 in order to form an electrical connection with adjacent solar cells or other circuitry. In some embodiments, both ends of the elongated solar cell are exposed by transparent tubular casing 310 in order to form an electrical connection with adjacent solar cells or other circuitry. More discussion of transparent tubular casings 310 that can be used in some embodiments of the present application are disclosed in U.S. patent application Ser. No. 11/378,847, which is hereby incorporated by reference herein in its entirety.

Optional water resistant layer. In some embodiments, one or more layers of water resistant material are coated over the solar cell to waterproof the cell. In some embodiments, this water resistant layer is coated onto transparent conductor 110, optional filler layer 330, optional transparent tubular casing 310, and/or an optional antireflective coating described below. For example, in some embodiments, such water resistant layers are circumferentially disposed onto optional filler layer 330 prior to encasing the solar cell 402 in optional transparent tubular casing 310. In some embodiments, such water resistant layers are circumferentially disposed onto transparent tubular casing 310 itself. In embodiments where a water resistant layer is provided to waterproof the solar cell, the optical properties of the water resistant layer are chosen so that they do not interfere with the absorption of incident light by the solar cell. In some embodiments, the water resistant layer is made of clear silicone, SiN, SiOₓN_{y}, SiOₓ, or Al₂O₃, where x and y are integers. In some embodiments, the water resistant layer is made of a Q-type silicone, a silsequioxane, a D-type silicon, or an M-type silicon.

Optional antireflective coating. In some embodiments, an optional antireflective coating is also disposed onto transparent conductor 110, optional filler layer 330, optional transparent tubular casing 310, and/or the optional water resistant layer described above in order to maximize solar cell efficiency. In some embodiments, there is a both a water resistant layer and an antireflective coating deposited on transparent conductor 110, optional filler layer 330, and/or optional transparent tubular casing 310.

In some embodiments, a single layer serves the dual purpose of a water resistant layer and an anti-reflective coating. In some embodiments, the antireflective coating is made of MgF₂, silicone nitrate, titanium nitrate, silicon monoxide (SiO), or silicon oxide nitrite. In some embodiments, there is more than one layer of antireflective coating. In some embodiments, there is more than one layer of antireflective coating and each layer is made of the same material. In some embodiments, there is more than one layer of antireflective coating and each layer is made of a different material.

Optional fluorescent material. In some embodiments, a fluorescent material (e.g., luminescent material, phosphorescent material) is coated on a surface of a layer of the solar cell. In some embodiments, the fluorescent material is coated on the luminal surface and/or the exterior surface of transparent conductor 110, optional filler layer 330, and/or optional transparent tubular casing 300. In some embodiments, the solar cell includes a water resistant layer and the fluorescent material is coated on the water resistant layer. In some embodiments, more than one surface of a solar cell is coated with optional fluorescent material. In some embodiments, the fluorescent material absorbs blue and/or ultraviolet light, which some semiconductor junctions 410 of the present application do not use to convert to electricity, and the fluorescent material emits light in visible and/or infrared light which is useful for electrical generation in some solar cells 300 of the present application.

Fluorescent, luminescent, or phosphorescent materials can absorb light in the blue or UV range and emit visible light. Phosphorescent materials, or phosphors, usually comprise a suitable host material and an activator material. The host materials are typically oxides, sulfides, selenides, halides or silicates of zinc, cadmium, manganese, aluminum, silicon, or various rare earth metals. The activators are added to prolong the emission time.

In some embodiments of the application, phosphorescent materials are incorporated in the systems and methods of the present application to enhance light absorption by the solar cell. In some embodiments, the phosphorescent material is directly added to the material used to make optional transparent tubular casing 310. In some embodiments, the phosphorescent materials are mixed with a binder for use as transparent paints to coat various outer or inner layers of solar cell 300, as described above.

Exemplary phosphors include, but are not limited to, copper-activated zinc sulfide (ZnS:Cu) and silver-activated zinc sulfide (ZnS:Ag). Other exemplary phosphorescent materials include, but are not limited to, zinc sulfide and cadmium sulfide (ZnS:CdS), strontium aluminate activated by europium (SrAlO₃:Eu), strontium titanium activated by praseodymium and aluminum (SrTiO3:Pr, Al), calcium sulfide with strontium sulfide with bismuth ((Ca,Sr)S:Bi), copper and magnesium activated zinc sulfide (ZnS:Cu,Mg), or any combination thereof.

Methods for creating phosphor materials are known in the art. For example, methods of making ZnS:Cu or other related phosphorescent materials are described in U.S. Pat. No. 2,807,587 to Butler et al.; U.S. Pat. No. 3,031,415 to Morrison et al.; U.S. Pat. No. 3,031,416 to Morrison et al.; U.S. Pat. No. 3,152,995 to Strock; U.S. Pat. No. 3,154,712 to Payne; U.S. Pat. No. 3,222,214 to Lagos et al.; U.S. Pat. No. 3,657,142 to Poss; U.S. Pat. No. 4,859,361 to Reilly et al., and U.S. Pat. No. 5,269,966 to Karam et al., each of which is hereby incorporated by reference herein in its entirety. Methods for making ZnS:Ag or related phosphorescent materials are described in U.S. Pat. No. 6,200,497 to Park et al., U.S. Pat. No. 6,025,675 to Ihara et al.; U.S. Pat. No. 4,804,882 to Takahara et al., and U.S. Pat. No. 4,512,912 to Matsuda et al., each of which is hereby incorporated herein by reference in its entirety. Generally, the persistence of the phosphor increases as the wavelength decreases. In some embodiments, quantum dots of CdSe or similar phosphorescent material can be used to get the same effects. See Dabbousi et al., 1995, “Electroluminescence from CdSe quantum-dot/polymer composites,” Applied Physics Letters 66 (11): 1316-1318; Dabbousi et al., 1997 “(CdSe)ZnS Core-Shell Quantum Dots: Synthesis and Characterization of a Size Series of Highly Luminescent Nanocrystallites,” J. Phys. Chem. B, 101: 9463-9475; Ebenstein et al., 2002, “Fluorescence quantum yield of CdSe:ZnS nanocrystals investigated by correlated atomic-force and single-particle fluorescence microscopy,” Applied Physics Letters 80: 1023-1025; and Peng et al., 2000, “Shape control of CdSe nanocrystals,” Nature 404: 59-61; each of which is hereby incorporated by reference herein in its entirety.

In some embodiments, optical brighteners are used in the optional fluorescent layers of the present application. Optical brighteners (also known as optical brightening agents, fluorescent brightening agents or fluorescent whitening agents) are dyes that absorb light in the ultraviolet and violet region of the electromagnetic spectrum, and re-emit light in the blue region. Such compounds include stilbenes (e.g., trans-1,2-diphenylethylene or (E)-1,2-diphenylethene). Another exemplary optical brightener that can be used in the optional fluorescent layers of the present application is umbelliferone(7-hydroxycoumarin), which also absorbs energy in the UV portion of the spectrum. This energy is then re-emitted in the blue portion of the visible spectrum. More information on optical brighteners is in Dean, 1963, Naturally Occurring Oxygen Ring Compounds, Butterworths, London; Joule and Mills, 2000, Heterocyclic Chemistry, 4^{th} edition, Blackwell Science, Oxford, United Kingdom; and Barton, 1999, Comprehensive Natural Products Chemistry 2: 677, Nakanishi and Meth-Cohn eds., Elsevier, Oxford, United Kingdom, 1999.

Layer construction. In some embodiments, some of the afore-mentioned layers are constructed using cylindrical magnetron sputtering techniques, conventional sputtering methods, or reactive sputtering methods on long tubes or strips. Sputtering coating methods for long tubes and strips are disclosed in for example, Hoshi et al., 1983, “Thin Film Coating Techniques on Wires and Inner Walls of Small Tubes via Cylindrical Magnetron Sputtering,” Electrical Engineering in Japan 103:73-80; Lincoln and Blickensderfer, 1980, “Adapting Conventional Sputtering Equipment for Coating Long Tubes and Strips,” J. Vac. Sci. Technol. 17:1252-1253; Harding, 1977, “Improvements in a dc Reactive Sputtering System for Coating Tubes,” J. Vac. Sci. Technol. 14:1313-1315; Pearce, 1970, “A Thick Film Vacuum Deposition System for Microwave Tube Component Coating,” Conference Records of 1970 Conference on Electron Device Techniques 208-211; and Harding et al., 1979, “Production of Properties of Selective Surfaces Coated onto Glass Tubes by a Magnetron Sputtering System,” Proceedings of the International Solar Energy Society 1912-1916, each of which is hereby incorporated by reference herein in its entirety.

Circumferentially disposed. In some embodiments of the present application, where substrate 102 is cylindrical or tubular, layers of material are successively circumferentially disposed on substrate 102 in order to form a solar cell. As used herein, the term “circumferentially disposed” is not intended to imply that each such layer of material is necessarily deposited on an underlying layer. In fact, methods by which such layers are molded or otherwise formed on an underlying layer can be used. Nevertheless, the term circumferentially disposed means that an overlying layer is disposed on an underlying layer such that there is no annular space between the overlying layer and the underlying layer. Furthermore, as used herein, the term circumferentially disposed means that an overlying layer is disposed on at least twenty percent, at least thirty percent, at least forty, percent, at least fifty percent, at least sixty percent, at least seventy percent, or at least eighty percent of the perimeter of the underlying layer. Furthermore, as used herein, the term circumferentially disposed means that an overlying layer is disposed along at least half of the length, at least seventy-five percent of the length, or at least ninety-percent of the underlying layer.

Circumferentially sealed. In the present application, the term circumferentially sealed is not intended to imply that an overlying layer or structure is necessarily deposited on an underlying layer or structure. In fact, the present application teaches methods by which such layers or structures (e.g., optional transparent tubular casing 310) are molded or otherwise formed on an underlying layer or structure. Nevertheless, the term circumferentially sealed means that an overlying layer or structure is disposed on an underlying layer or structure such that there is no annular space between the overlying layer or structure and the underlying layer or structure. Furthermore, as used herein, the term circumferentially sealed means that an overlying layer is disposed on the full perimeter of the underlying layer. In some embodiments, a layer or structure circumferentially seals an underlying layer or structure when it is circumferentially disposed around the full perimeter of the underlying layer or structure and along the full length of the underlying layer or structure. However, the present application contemplates embodiments in which a circumferentially sealing layer or structure does not extend along the full length of an underlying layer or structure.

4.1.1 Electrically Isolating Grooves

An embodiment of the present application provides systems, apparatus, and methods for constructing a groove in at least one common layer (e.g., back-electrode 104, semiconductor junction 410, transparent conductor 110, counter-electrode 420, filler layer 330) on a substrate 102. The at least one common layer is used, for example, to form one or more photovoltaic cells in a solar cell. A primary laser beam pass is made over an area on the at least one common layer thereby creating a groove with a heat affected zone in one or more layers of the at least one common layer. Then, one or more secondary laser beam passes is made through the heat affected zone thereby removing at least a portion of the heat affected zone in the at least one common layer. Such a groove has a first side and a second side that are electrically isolated from each other.

In some embodiments, a primary laser beam pass through an area is a sweep of a laser beam across an area or proximal to an area on at least one common layer that is ultimately patterned to form photovoltaic units of a solar cell. The primary laser beam pass melts at least a portion of the at least one common layer underlying the area. Then, the one or more secondary laser beam passes provide additional energy that remove residual left from the primary laser beam pass, thereby forming, or enlarging, an electrically isolating groove.

Electrically isolating grooves. Central to the formation of photovoltaic units of a solar cell is the creation of electrically isolating grooves in one or more common layers. However, such electrically isolating grooves can be used for other purposes such as in microchip fabrication or other micromachining applications. In some embodiments, a groove is electrically isolating when the resistance across the groove (e.g., from a first side of the groove to a second side of the groove) is 10 ohms or more, 20 ohms or more, 50 ohms or more, 1000 ohms or more, 10,000 ohms or more, 100,000 ohms or more, 1×10⁶ ohms or more, 1×10⁷ ohms or more, 1×10⁸ ohms or more, 1×10⁹ ohms or more, or 1×10¹⁰ ohms or more. For example, referring to FIG. 2C, groove 292 may be formed by scribing a common back-electrode 104, groove 294 may be formed by scribing a common semiconductor junction 410, and groove 296 may be formed by scribing a common transparent conductor 110.

Referring to FIG. 2C, because grooves 292 and 296 are created in conductive material (top and back-electrodes), the grooves fully extend through the respective back-electrode 104 and transparent conductor 110 to ensure that the grooves are electrically isolating. For example, for a planar solar cell (depicted as solar cell 100 in FIG. 1A), electrically isolating grooves 292 and 296 traverse an entire length or width of a selected layer. For cylindrical solar cells (depicted as solar cell 300 in FIGS. 2A to 2E), grooves 292 and 296 are respectively scribed around the entire circumference of back-electrode 104 and transparent conductor 110. Groove 294 (also referred to as via 280 once the groove is filled with the end-point material) differs from grooves 292 and 296 in the sense that the groove, once filled with material, does conduct current. Groove 294 is created to connect a back-electrode 104 with transparent conductor 110, so that current flows through via 280 (formed by groove 294 once it is filled) from a back-electrode 104 and a transparent conductor 110. Nevertheless, there is still little or no current flowing from one side of a via 280 to the other side of the same via 280.

Referring to FIGS. 2A through 2E, solar cell unit 300 comprises a substrate 102 common to a plurality of photovoltaic cells 700. The plurality of photovoltaic cells 700 are linearly arranged on substrate 102 as illustrated in FIG. 2E. Each photovoltaic cell 700 in the plurality of photovoltaic cells 700 comprises a back-electrode 104 circumferentially disposed on common substrate 102 and a semiconductor junction 410 circumferentially disposed on the back-electrode 104. In the case of FIGS. 2A through 2E, semiconductor junction 410 comprises an absorber 106 and a window layer 108. Each photovoltaic cell 700 in the plurality of photovoltaic cells 700 further comprises a transparent conductor 110 circumferentially disposed on the semiconductor junction 410. In the case of FIGS. 2A through 2E, the transparent conductor 110 of the first photovoltaic cell 700 is in serial electrical communication with the back-electrode of the second photovoltaic cell 700 in the plurality of photovoltaic cells because of vias 280. In some embodiments, each via 280 extends the full circumference of the solar cell. In some embodiments, each via 280 does not extend the full circumference of the solar cell. In fact, in some embodiments, each via 280 only extends a small percentage of the circumference of the solar cell. In some embodiments, each photovoltaic cell 700 may have one, two, three, four or more, ten or more, or one hundred or more vias 280 that electrically connect in series the transparent conductor 110 of the photovoltaic cell 700 with back-electrode 104 of an adjacent photovoltaic cell 700.

Heat affected zone (HAZ) and laser beam pass. Laser scribing provides the accuracy and precision necessary for photovoltaic cell (e.g., thin film and thick film types) patterning. However, laser scribing on photovoltaic cells is made more complex because of the wide range of materials involved. For example, commonly present materials in photovoltaic cells are metals, semiconductors, and wide-band-gap conductive oxides. These materials absorb laser radiations at different wavelengths, and have different thermal expansion coefficients as well as melting points. In particular, these materials differ in their heat capacities: the ability to absorb and transfer heat generated from laser irradiation. Heat capacity of a material directly relates to how fast and how far heat transfers within a material. Heat capacity of a material therefore directly contributes to the width and depth of a HAZ.

In some embodiments, a primary laser beam pass warms and melts an area on at least one common layer (back-electrode 104, semiconductor junction 410, transparent conductor 110, and/or filler layer 330). The extent of melting is determined by the interaction between the material that constitutes the common layer and the incident laser beam. In some embodiments, this primary laser beam pass creates a groove bordered by a heat affected zone. To ensure that the groove is electrically isolating, conductive elements in HAZ are exposed to one or more secondary laser beam passes following the primary laser beam pass that created the groove bordered by the HAZ. In some embodiments, there is one or more, two or more, three or more, four or more, five or more, six or more, seven or more, eight or more, nine or more, ten or more, or fifteen or more secondary laser beam passes, which can collectively be referred to as the second pass. In some embodiments, an electrically isolating groove (e.g., 292, 294 or 296 as depicted in FIGS. 2C and 2E) fully penetrates a single layer. Alternatively, in some embodiments, an electrically isolating groove (e.g., 294 as depicted in FIGS. 2C and 2E) fully penetrates more than one layer.

4.1.2 Exemplary Primary and Secondary Laser Beam Passes

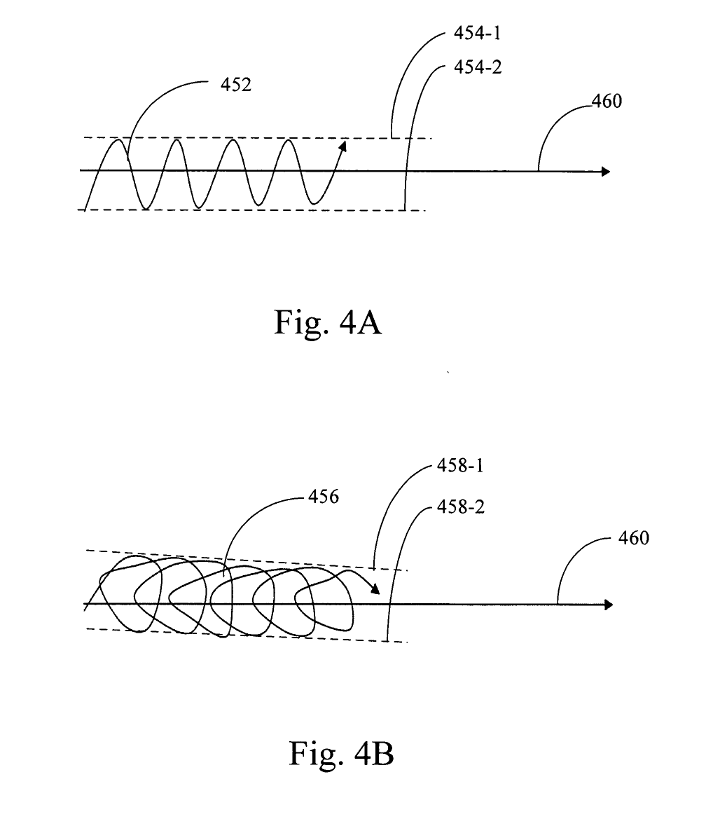

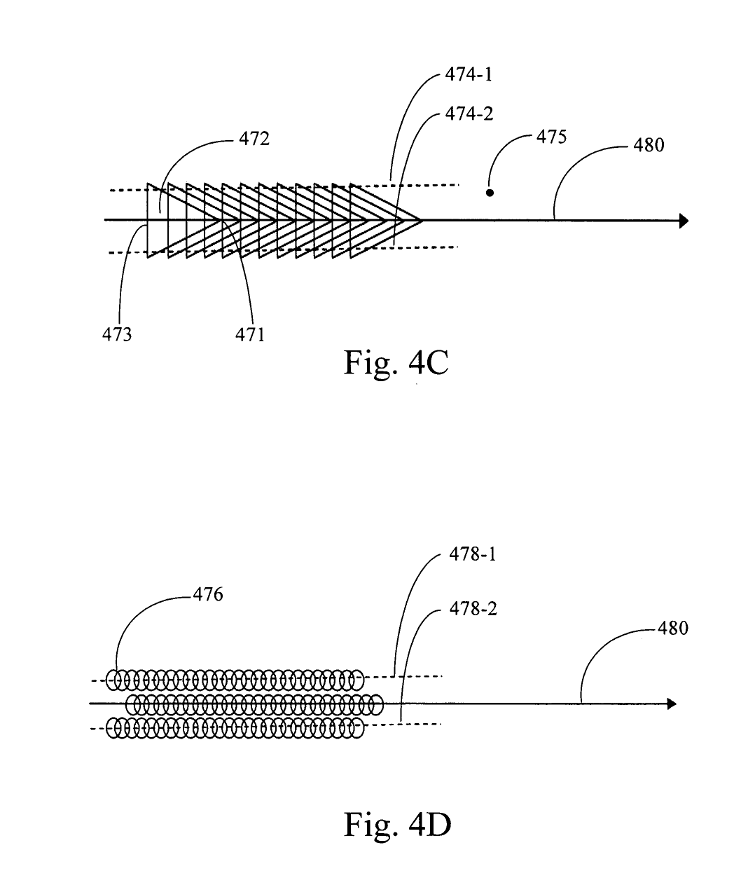

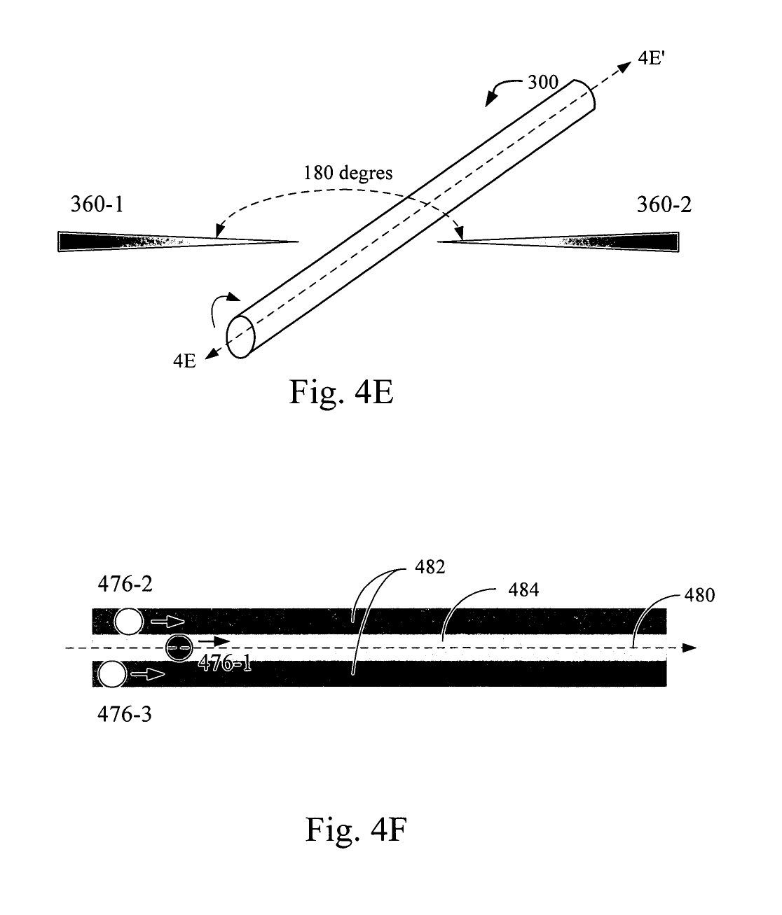

In some embodiments, an electrically isolating groove is created by a primary laser beam pass as well as one or more secondary laser beam passes over an area on one or more common layers. In the present application, (i) a laser beam and (ii) a designated area on one or more common layers are moved in one or more dimensions relative to each other during the primary laser beam pass and the one or more secondary laser beam passes. Non-limiting exemplary motions that may be used to make these laser beam passes are described in this section and are illustrated in FIG. 4. As used herein, in some embodiments, the terms “primary laser beam pass” and “first pass” are used interchangeably. As used herein, in some embodiments, the terms “one or more secondary laser beam passes” and “second pass” are used interchangeably.

In some embodiments, a primary laser beam pass and/or one or more secondary laser beam passes are generated by a laser beam moving in a single dimension relative to an area on one or more common layers. In some embodiments, a primary laser beam pass and/or one or more secondary laser beam passes are generated by a laser beam moving in a periodic motion relative to an area on one or more common layers. In some embodiments, a primary laser beam pass and/or one or more secondary laser beam passes are generated by a laser beam moving in a non-periodic motion relative to an area on one or more common layers. For example, in some embodiments, a laser generating a laser beam creates trail 452 (FIG. 4A) on the one or more common layers. In some embodiments, the one or more common layers are moved in a translational motion in direction 460 while the laser beam is moved in path 452. In some embodiments, the primary laser beam used for the primary laser beam pass and/or the secondary laser beams used for the one or more secondary laser beam passes are moved in a back and forth translational movement in a path that is anywhere from zero to ninety degrees away from direction 460 while the one or more common layers are moved in direction 460 thereby creating a periodic path such as path 452 or a nonperiodic path. In some embodiments, such laser beams are moved in direction 460 and the one or more common layers are held stationary.

In some embodiments, a laser beam used for the primary and/or one or more secondary laser beam passes moves in an oscillatory motion between a first position and a second position. In such embodiments, the laser beam may oscillate between one point and another point on the area on the one or more common layers at a frequency of 0.1 Hz or more, 10 Hz or more, 100 Hz or more, 1,000 Hz or more, or 10,000 Hz or more. In some embodiments, the laser beam moves in such a way that it oscillates between a first and second position, where the first and second position are 0.05 micrometers or more apart from each other, 0.5 micrometers or more apart from each other, 5 micrometers or more apart from each other, 50 micrometers or more apart from each other, 5.0×10² micrometers or more apart from each other, 5.0×10³ micrometers or more apart from each other, or 5.0×10⁴ micrometers or more apart from each other. In such embodiments, the distance between the first position and the second position determines the distance between melting edges (e.g., 454-1 and 454-2 in FIG. 4A) of a laser beam trail 452.

In some embodiments, substrate 102 bearing one or more common layers is held stationary and a laser beam used for a laser beam pass (the primary laser beam pass or one of the one or more secondary laser beam passes) is moved in direction 460 at a rate of 2 centimeter per second (cm/sec) or more, 20 cm/sec or more, 200 cm/sec or more, 2,000 cm/sec or more, or 20,000 cm/sec or more. In some embodiments, a laser beam used for a laser beam pass (the primary laser beam pass or one of the one or more secondary laser beam passes) is held stationary and substrate 102 bearing one or more common layers is moved in direction 460 at a rate of 2 cm/sec or more, 20 cm/sec or more, 200 cm/sec or more, 2,000 cm/sec or more, or 20,000 cm/sec or more.

In some embodiments, substrate 102 is cylindrical and is rotated about its single elongated axis during the primary laser beam pass or one or more of the secondary laser beam passes. In some embodiments, a cylindrical substrate 102 is rotated at a rate of 2 rounds per minute (rpm) or more, 20 rpm or more, 200 rpm or more, 2,000 rpm or more, or 20,000 rpm or more. In some embodiments, such a rotating substrate is also transitionally moved relative to the laser beam. For instance, the substrate may be moved at a rate of 2 cm/sec or more, 20 cm/sec or more, 200 cm/sec or more, 2,000 cm/sec or more, or 20,000 cm/sec or more relative to the laser beam.

In some embodiments, a primary laser beam pass and/or one or more secondary laser beam passes are generated by a laser beam moving in a periodic motion relative to an area on one or more common layers. In some embodiments, a laser beam moves in a saw-tooth, rectangular, square, spiral, zig-zag, or sine or cosine motion relative to such an area. For example, as depicted in FIG. 4B, in some embodiments, a laser beam (e.g., for the primary laser beam pass and/or one or more secondary laser beam passes) moves in a periodic motion that combines an oscillation motion with an additional translational motion in direction 460. In some such embodiments, the laser beam oscillates between a first position and a second position that are 0.05 micrometers or more apart, 0.5 micrometers or more apart, 5 micrometers or more apart, 50 micrometers or more apart, 5.0×10² micrometers or apart, 5.0×10³ micrometers or more apart, 5.0×10⁴ micrometers or more apart. The distance between this first and second position separates the melting edges (e.g., 458-1 and 458-2 in FIG. 4B) of a laser beam trail 456. In some embodiments, the laser beam moves at a translational rate of 2 cm/sec or more, 20 cm/sec or more, 200 cm/sec or more, 2,000 cm/sec or more, or 20,000 cm/sec or more, relative to the area on the one or more common layers.

In some embodiments, a primary laser beam pass and one or more secondary laser beam passes are generated by a laser beam moving in a non-periodic motion in two or more different directions relative to a scribing layer. For example, a laser beam moves in a non-periodic rectangular, non-periodic square, non-periodic spiral, non-periodic zig-zag, or jagged motion relative to the area on the one or more common layers. In the non-periodical movement embodiments, the distance separating the melting edges (e.g., 458-1 and 458-2 in FIG. 4A) of a laser beam trail 456 is application dependent.

In some embodiments, an area on the one or more common layers moves in rotational and translational motions relative to a laser beam used for the primary laser beam pass and/or one or more secondary laser beam passes. In one example, the area is on a layer circumferentially disposed on a cylindrical substrate 102 (e.g. on layer 104, 106, 108, 110, 410, or 415 in FIGS. 1A, 2A through 2E) and the rotational motion is caused by rotating the cylindrical substrate 102 at a rotational rate of 2 rounds per minute (rpm) or more, 20 rpm or more, 200 rpm or more, 2,000 rpm or more, or 20,000 rpm or more while the laser beam does not undergo such a rotational movement. In some embodiments during rotation of the substrate, an area on the one or more common layers moves in a translational direction (e.g. direction 460 of FIG. 4B) at a rate of 2 cm/sec or more, 20 cm/sec or more, 200 cm/sec or more, 2,000 cm/sec or more, or 20,000 cm/sec or more, relative to the laser beam as depicted in FIGS. 4A and 4B.

Multiple beams or a beam with multiple components. In some embodiments, the primary laser beam pass and one or more secondary laser beam passes are generated by two or more laser beams. Alternatively, in other embodiments, the primary laser beam pass and one or more secondary laser beam passes are generated by a specialized laser beam with two or more components. In some embodiments, a first laser beam and a second laser beam move in translational motion in a sequential manner such that the second laser beam follows the first laser beam to further ablate the HAZ. The first laser beam (primary laser beam) is referred to as the melting beam, and the second laser beam (one or more secondary laser beams) are referred to as the ablating beam. For example, referring to FIG. 4A, a first melting laser beam oscillates between a first position and a second position, while a second ablating laser beam oscillates between a third position and a fourth position to generate a similar trail 452 with a time delay (e.g. a time delay of one or more microseconds, one or more seconds, one or more minutes) from the first melting laser beam to further ablate the HAZ. Residual melted material is further evaporated by the ablating beam. Similarly, referring to FIG. 4B, a first laser beam oscillates between a first position and a second position, while a second laser beam oscillates between a third position and a fourth position to generate a similar trail 456 with a time delay (e.g. a time delay of one or more microseconds, one or more seconds, one or more minutes) from the first laser beam to further ablate any area that is affected by the first laser beam.

In some embodiments, more than two laser beams (the primary and at least one secondary) are necessary to fully ablate any previously affected area to ensure the formation of an electrically isolating groove (e.g., groove 292, 294 or 296 of FIG. 2E). In some embodiments, the first laser beam is visually separated from the second laser beam. In other embodiments, the first laser beam is not visually separated from the second laser beam. In some embodiments, the first laser beam and the second laser beam move relative to the area on the one or more common layers to create the primary laser beam pass and one or more secondary laser beam passes. In some embodiments, the first laser beam and the second laser beam move in a sequential fashion with respect to each other.

Alternatively, in other embodiments, the primary laser beam pass and one or more secondary laser beam passes are generated by a specialized laser beam with two or more components. For example, referring to FIG. 4A, a first laser beam component oscillates between a first position and a second position, while a second laser beam component oscillates between a third position and a fourth position to generate a similar trail 452 with a time delay (e.g. a time delay of one or more microseconds, one or more seconds, one or more minutes) from the first laser beam to further ablate any area that is affected by the first laser beam component. Similarly, referring to FIG. 4B, a first laser beam component oscillates between a first and second position, while a second laser beam component oscillates between a third and fourth position to generate the same trail 456 with a time delay (e.g. a time delay of one or more microseconds, one or more seconds, one or more minutes) from the first laser beam to further ablate any area that is affected by the first laser beam component. In some embodiments, more than two laser beam components are necessary to fully ablate any previously affected area to ensure the formation of an electrically isolating groove 292, 294 or 296. In some embodiments, a first laser beam component is visually separated from a second laser beam component. In other embodiments, a first laser beam component is not visually separated from a second laser beam component (e.g., the two components adjoin each other). In some embodiments, a first laser beam component and a second laser beam component move relative to a designated area to create the primary laser beam pass and one or more secondary laser beam passes. In some embodiments, a first laser beam component and a second laser beam component move in a sequential fashion with respect to each other.

An exemplary embodiment is depicted in FIG. 4E. A cylindrical solar cell 300 is placed along axis 4E-4E′. Laser beams 360-1 and 360-2 illuminate solar cell 300 from two different directions. For example, as illustrated, laser beams 360-1 and 360-2 are on opposite sides of solar cell 300. Thus, as depicted in FIG. 4E, laser beams 360-1 and 360-2 are 180 degrees apart. However, in other embodiments, laser beams 360-1 and 360-2 are positioned such that they are radially between 2 and 180 degrees apart from each other. Solar cell 300 rotates about axis 4E-4E′. Each laser beam 360 exposes the area that has been previously melted by the other laser beam. In embodiments where the two laser beams are synchronized, the time lag between laser beams 360-1 and 360-2 depends upon the rotational speed of solar cell 300. The same is true for laser beam 360-1 due to the symmetrical configuration. In some embodiments, the laser beams are radially separated by an angle other than 180 degrees. For example, in some embodiments, laser beams 360-1 and 360-2 are separated by 5 degrees or more, 10 degrees or more, 20 degrees or more, 45 degrees or more, 60 degrees or more, or 100 degrees or more. In some embodiments, the two laser beams are split from a single laser. In some embodiments, the two laser beams are generated by different lasers. In some embodiments, the concept is extended such that there are three or more laser beams radially disposed about the solar cell, four or more laser beams radially disposed about the solar cell, five or more laser beams radially disposed about the solar cell, or more.

4.1.3 Predetermined Laser Beam

Exemplary methods are also provided to create a primary laser beam pass and one or more secondary beam passes through an area on one or common layers, as depicted, for example, in FIGS. 4C and 4D. In some embodiments, one or more laser beams illuminate an area on one or more common layers in a predetermined shape (e.g., a triangle-shape 472 in FIG. 4C, or an arrow-like shape in FIG. 4D). The illuminated area with a predetermined shape is referred to as a beam area. In such embodiments, at a specific instance of time, a given point on one or more common layers (e.g., 475 in FIG. 4C) is affected differently by different portions of the beam area. For example, referring to FIG. 4C, as a laser beam travels along a path defined by direction 480, the triangular shaped beam area 472 affects point 475 first at its leading point 471 and last, at its back edge 473. Even though point 475 does not lie directly in the path of leading point 471, it may be melted or thermally affected as leading point 471 approaches due to the HAZ effects. The melted or thermally affected point 475 is subsequently illuminated by another portion of triangle 472. The additional laser energy further melts or evaporates already melted material at or adjacent to point 475. Any residual material may be cleaned up when back beam edge 473 passes through point 475. Here, the primary laser beam pass and one or more secondary laser beam passes are achieved by various portions of the specialized laser beam that illuminates in a predetermined shape (e.g. the triangular shape depicted in FIG. 4C) to create an electrically isolating groove. The width of the groove is determined by the length of the back edge 473, and is illustrated in FIG. 4C by the boundaries of melting edges 474. The size and shape of the illuminated beam area, the speed at which triangular laser beam 472 travels along direction 480 relative to the area on the one or more common layers, and inherent characteristics of the laser beam (e.g., pulse duration, intensity, etc.) are set so that that the resulting groove is electrically insulating.

In some embodiments, the predetermined shape is triangular (e.g., 472 in FIG. 4C), trapezoidal, half-circular, circular or elliptical. In some embodiments, a beam area with a predetermined shape is formed by a predetermined laser beam. In other embodiments, the beam area may be formed collectively by a group of laser beams, as depicted in FIG. 4D. Referring to FIG. 4D, several circular laser beams 476 collectively form an arrow or triangular shaped beam area. In essence, the beam area passes a given point on the scribing surface with a time delay between its first and leading edge and a second or trailing edge. Effectively, multiple laser beam passes are achieved by different laser beams that collectively form the predetermined illuminated area to create an electrically isolating groove. The width of the groove is defined by the separation between laser beams that collectively form the predetermined illuminated area, depicted by the boundaries of melting edges 478. Similar to the single laser beam embodiments, the size and shape of the illuminated area, the speed at which the laser beams 476 travels along direction 480 relative to the scribing surface, and inherent characteristics of the laser beam (e.g., pulse duration, intensity, etc.) may be adjusted such that the resulting groove is electrically isolating.

A mechanism for how multiple lasers can collectively create a single laser beam pass is detailed in FIG. 4F. As laser beam 476-1 travels along direction 480 on one or more common layers, it creates a direct beam path 484 along which materials constituting the one or more common layers are melted or evaporated. Laser beam 476-1 further creates additional paths 482 parallel to 480 in what is known as the heat affected zone. Materials constituting at least one of the one or more common layers in these regions are not as thermally affected as those directly within path 480. Laser beams 476-2 and 476-3 are moved along paths 482 after laser beam 476-1 has made its pass. In this way, a majority of the additional energy from laser beam 476-2 is used to evaporate or ablate the already melted materials along path 482 instead of being further spread to create a larger heat affected zone. Pulse duration, time delay, and other parameters may be adjusted to ensure clean ablation of residual materials from laser beam 476-1. In some embodiments, only two laser beams, rather than the three used in FIG. 4F, are used to ensure that the resulting groove is electrically isolating. In some embodiments, more than three laser beams are used to make an electrically isolating groove.

4.1.4 Exemplary Laser Scribing Processes

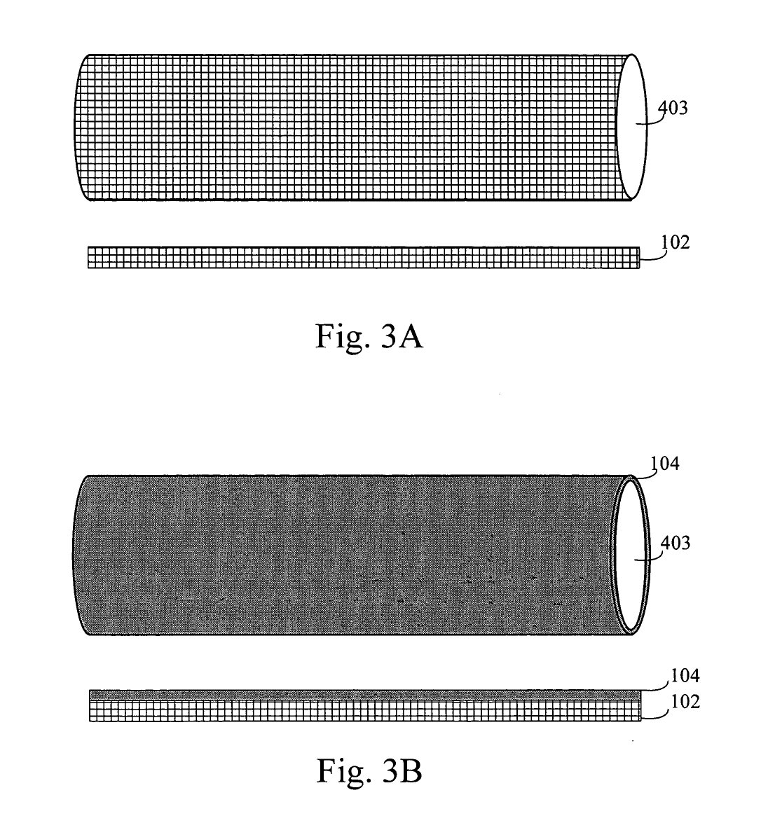

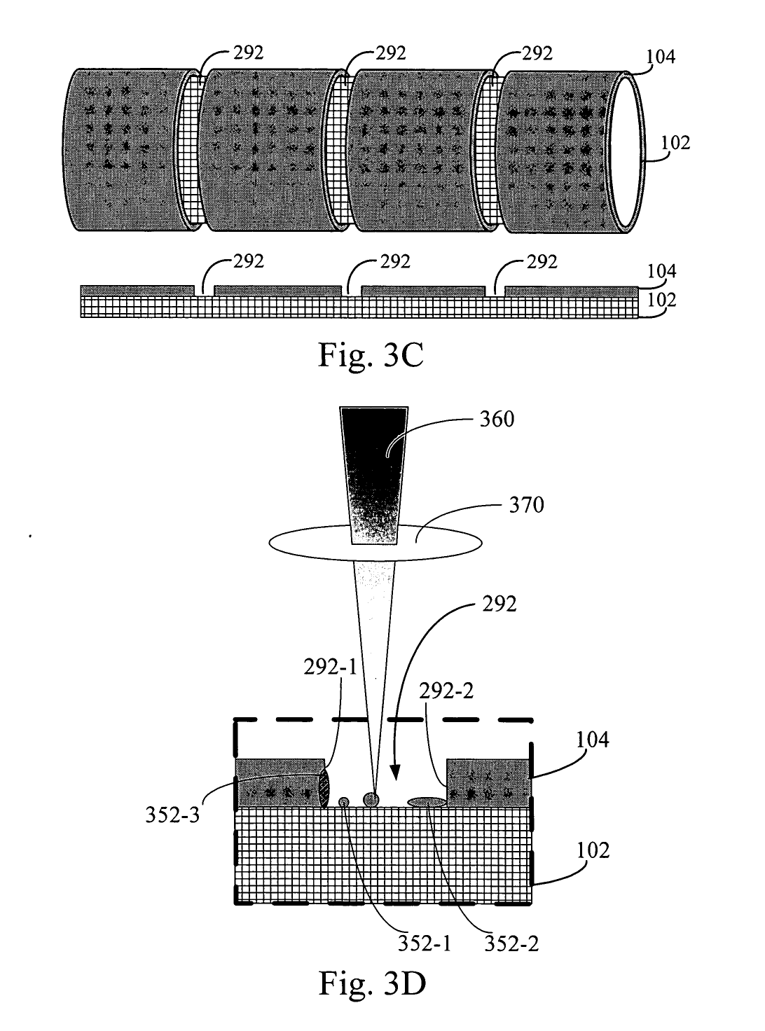

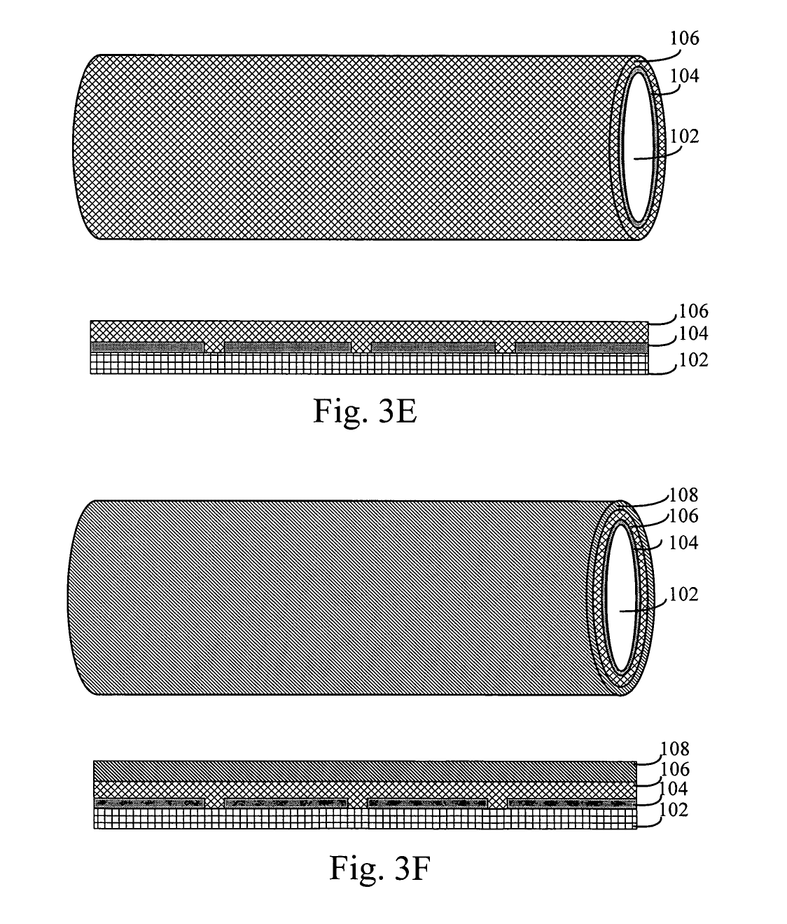

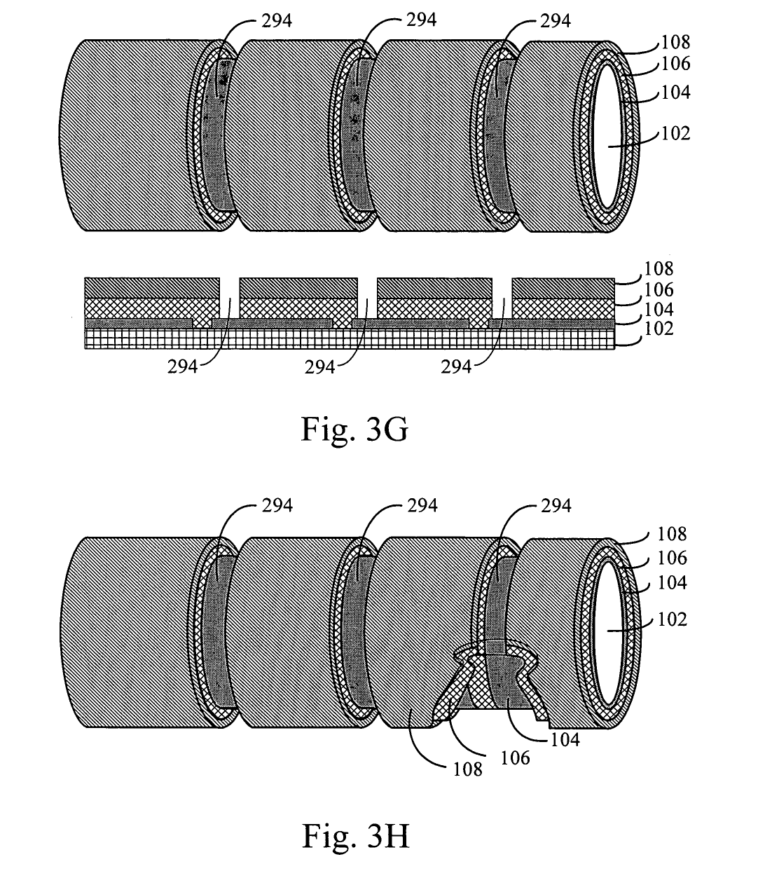

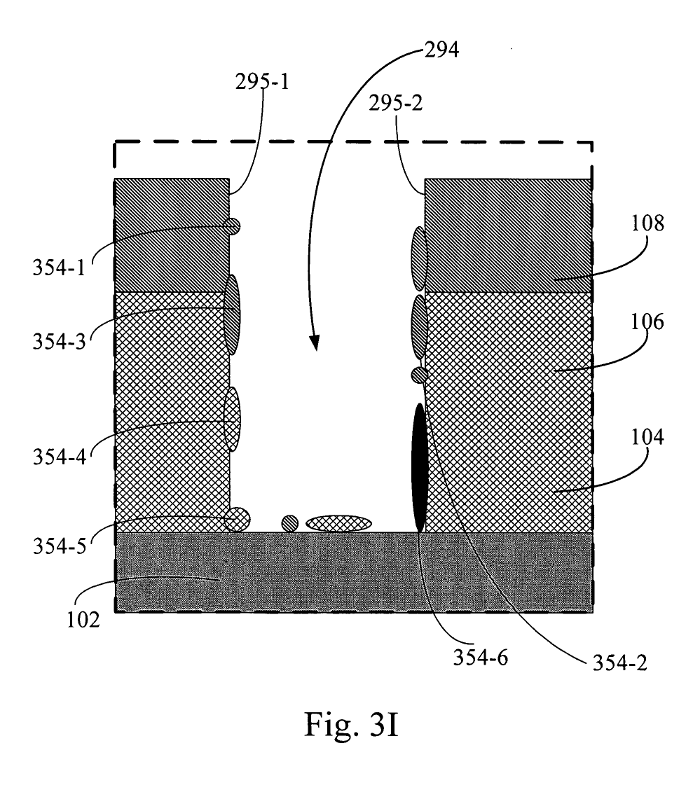

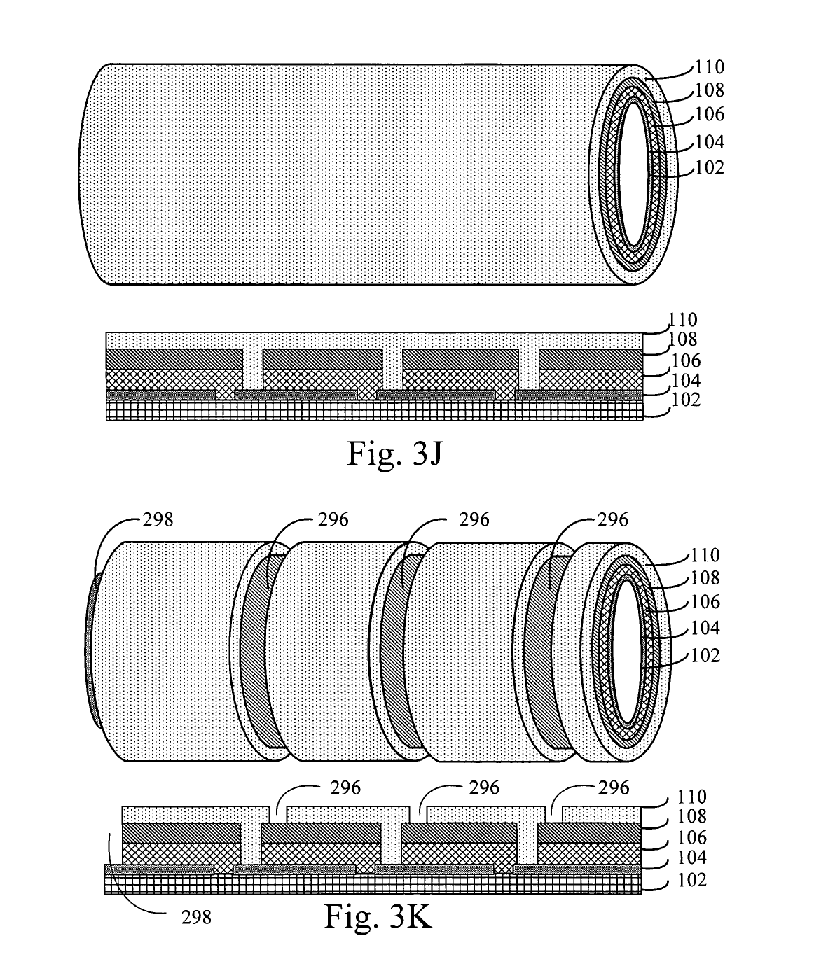

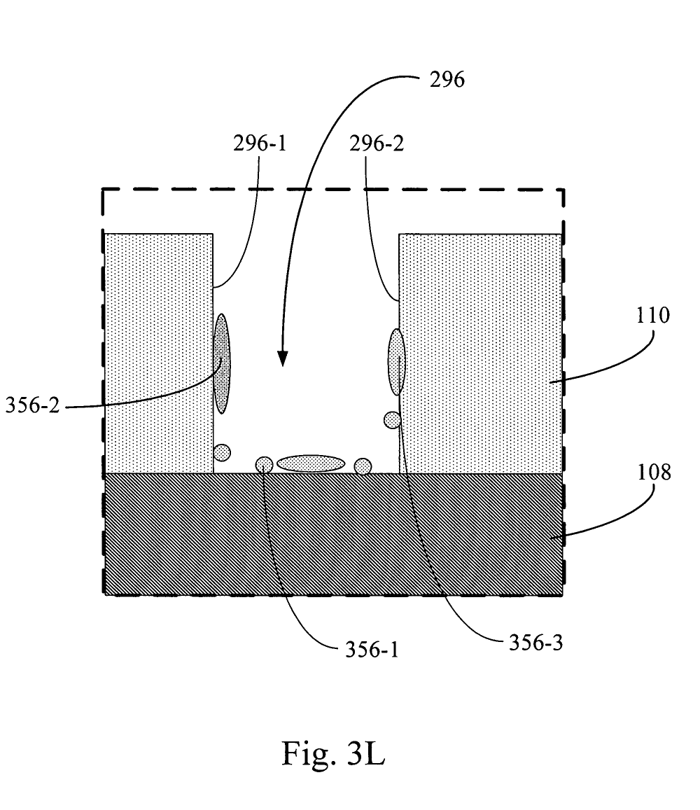

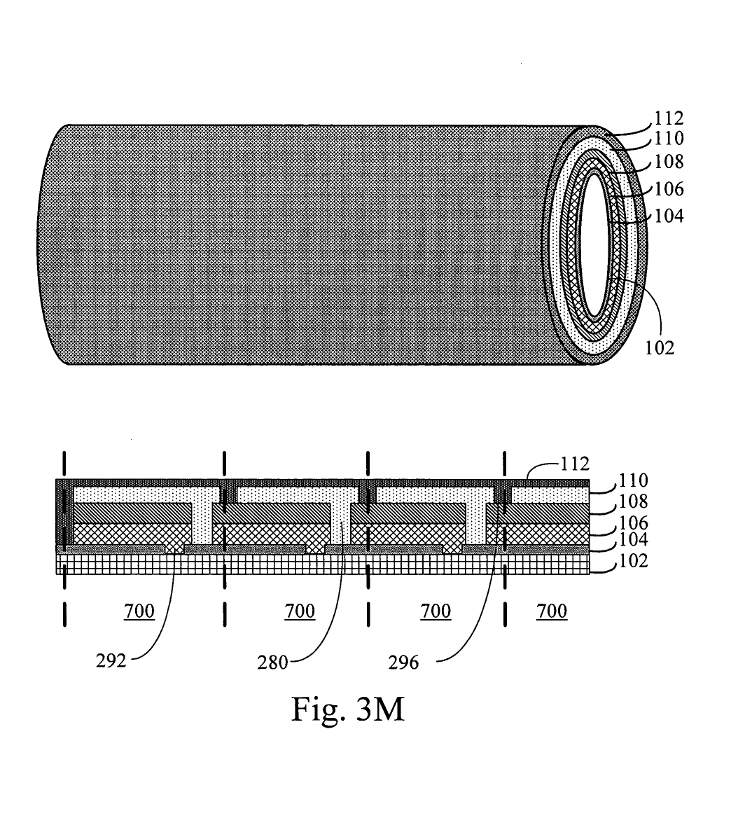

FIG. 3 illustrates exemplary processing steps for manufacturing a solar cell using techniques disclosed in the present application. Other manufacturing techniques for manufacturing cylindrical monolithically integrated solar cells, and other forms of monolithically integrated cylindrical solar cells are disclosed in U.S. patent application Ser. No. 11/158,178, filed Jun. 20, 2005; Ser. No. 11/248,789, filed Oct. 11, 2005; Ser. No. 11/315,523, filed Dec. 21, 2005; Ser. No. 11/329,296, filed Jan. 9, 2006; Ser. No. 11/378,835, filed Mar. 18, 2006; Ser. No. 11/378,847, filed Mar. 18, 2006; Ser. No. 11/396,069, filed Mar. 30, 2006; and U.S. patent application Ser. No. 11/437,928, filed May 19, 2006, each of which is hereby incorporated by reference herein in its entirety.

FIG. 3 shows the perspective view of a solar cell in various stages of manufacture. Below each view is a corresponding cross-sectional view of one hemisphere of the corresponding solar cell. In typical embodiments, the solar cell illustrated in FIG. 3 does not have an electrically conducting substrate 102. In the alternative, in embodiments where substrate 102 is electrically conducting, the substrate is circumferentially wrapped with an insulator layer so that back-electrodes 104 of individual photovoltaic cells 700 are electrically isolated from each other.

Referring to FIG. 3A, the process begins with substrate 102. Substrate 102 is solid cylindrical shaped or hollowed cylindrical shaped. In some embodiments, substrate 102 is either (i) tubular shaped or (ii) a rigid solid rod shaped. Next, in FIG. 3B, back-electrode 104 is circumferentially disposed on substrate 102. Back-electrode 104 may be deposited by a variety of techniques, including some of the techniques disclosed in U.S. patent application Ser. No. 11/378,835, filed Mar. 18, 2006, which is hereby incorporated by reference herein in its entirety. In some embodiments, back-electrode 104 is circumferentially disposed on substrate 102 by sputtering or electron beam evaporation. In some embodiments, substrate 102 is made of a conductive material. In such embodiments, it is possible to circumferentially dispose back-electrode 104 onto substrate 102 using electroplating. In some embodiments, substrate 102 is not electrically conducting but is wrapped with a metal foil such as a steal foil or a titanium foil. In these embodiments, it is possible to electroplate back-electrode 104 onto the metal foil using electroplating techniques. In still other embodiments, back-electrode 104 is circumferentially disposed on substrate 102 by hot dipping.

Referring to FIG. 3C, back-electrode 104 is patterned in order to create grooves 292. Grooves 292 run the full perimeter of back-electrode 104, thereby breaking the back-electrode 104 into discrete sections. Each section serves as the back-electrode 104 of a corresponding photovoltaic cells 700. The bottoms of grooves 292 expose the underlying substrate 102. In some embodiments, grooves 292 are scribed using a laser beam having a wavelength that is absorbed by back-electrode 104.

FIG. 3D provides a schematic illustration of a set-up in accordance with the present application. After a primary laser beam pass (e.g., laser beam 360 as depicted in FIG. 3D), groove 292 contains residual 352 scattered on its sides and bottom. One or more secondary laser beam passes further sweeps away, by evaporation or ablation, residual material 352. In some embodiments, laser beam 360 is further modified, for example, by lens 370. It is not necessary to fully remove all residual 352 from the sides or bottom of groove 292 so long as the groove is electrically isolating. Because layer 104 is conductive, at least a portion of groove 292 must fully penetrate layer 104 to ensure that the groove is electrically isolating.

Forming groove 292 using laser scribing is advantageous over traditional machine cutting methods. Laser cutting of metal materials can be divided into two main methods: vaporization cutting and melt-and-blow cutting. In vaporization cutting, the material is rapidly heated to vaporization temperature and removed spontaneously as vapor. The melt-and-blow method heats the material to melting temperature while a jet of gas blows the melt away from the surface. In some embodiments, an inert gas (e.g., Ar) is used. In other embodiments, a reactive gas is used to increase the heating of the material through exothermal reactions with the melt. The thin film materials processed by laser scribing techniques include the semiconductors (e.g., cadmium telluride, copper indium gallium diselenide, and silicon), the transparent conducting oxides (e.g., fluorinedoped tin oxide and aluminum-doped zinc oxide), and the metals (e.g., molybdenum and gold). Such laser systems are all commercially available and are chosen based on pulse durations and wavelength. Some exemplary laser systems that may be used to laser scribe include, but are not limited, to those disclosed in Section 4.2. Examples of laser systems include Q-switched Nd:YAG laser systems, a Nd:YAG laser systems, copper-vapor laser systems, a XeCl-excimer laser systems, a KrFexcimer laser systems, and diode-laser-pumped Nd:YAG systems. See Compaan et al., 1998, “Optimization of laser scribing for thin film PV module,” National Renewable Energy Laboratory final technical progress report April 1995-October 1997; Quercia et al., 1995, “Laser patterning of CuInSe₂/Mo/SLS structures for the fabrication of CuInSe₂ sub modules,” in Semiconductor Processing and Characterization with Lasers: Application in Photovoltaics, First International Symposium, Issue 173/174, Number corn P: 53-58; and Compaan, 2000, “Laser scribing creates monolithic thin film arrays,” Laser Focus World 36: 147-148, 150, and 152, each of which is hereby incorporated by reference herein in its entirety, for detailed laser scribing systems and methods that can be used in the present application. In some embodiments, grooves 292 are scribed using mechanical means. For example, a razor blade or other sharp instrument is dragged over back-electrode 104 thereby creating grooves 292. In some embodiments grooves 292 are formed using a lithographic etching method.

FIGS. 3E & 3F illustrate the case in which semiconductor junction 410 comprises a single absorber layer 106 and a single window layer 108 that are disposed on back-electrode 104. However, the application is not so limited. For example, junction layer 410 can be a homojunction, a heterojunction, a heteroface junction, a buried homojunction, a p-i-n junction, or a tandem junction. Referring to FIG. 3E, absorber layer 106 is circumferentially disposed on back-electrode 104. In some embodiments, absorber layer 106 is circumferentially deposited onto back-electrode 104 by thermal evaporation. For example, in some embodiments, absorber layer 106 is CIGS that is deposited using techniques disclosed in Beck and Britt, Final Technical Report, January 2006, NREL/SR-520-39119; and Delahoy and Chen, August 2005, “Advanced CIGS Photovoltaic Technology,” subcontract report; Kapur et al., January 2005 subcontract report, NREL/SR-520-37284, “Lab to Large Scale Transition for Non-Vacuum Thin Film CIGS Solar Cells”; Simpson et al., October 2005 subcontract report, “Trajectory-Oriented and Fault-Tolerant-Based Intelligent Process Control for Flexible CIGS PV Module Manufacturing,” NREL/SR-520-38681; and Ramanathan et al., 31^{st} IEEE Photovoltaics Specialists Conference and Exhibition, Lake Buena Vista, Fla., Jan. 3-7, 2005, each of which is hereby incorporated by reference herein in its entirety. In some embodiments, absorber layer 106 is circumferentially deposited on back-electrode 104 by evaporation from elemental sources. For example, in some embodiments, absorber layer 106 is CIGS grown on a molybdenum back-electrode 104 by evaporation from elemental sources. One such evaporation process is a three stage process such as the one described in Ramanthan et al., 2003, “Properties of 19.2% Efficiency ZnO/CdS/CuInGaSe₂ Thin-film Solar Cells,” Progress in Photovoltaics: Research and Applications 11, 225, which is hereby incorporated by reference herein in its entirety, or variations of the three stage process. In some embodiments, absorber layer 106 is circumferentially deposited onto back-electrode 104 using a single stage evaporation process or a two stage evaporation process. In some embodiments, absorber layer 106 is circumferentially deposited onto back-electrode 104 by sputtering. Typically, such sputtering requires a substrate 102 to be heated during deposition of the back-electrode.

In some embodiments, absorber layer 106 is circumferentially deposited onto back-electrode 104 as individual layers of component metals or metal alloys of the absorber layer 106 using electroplating. For example, consider the case where absorber layer 106 is copper-indium-gallium-diselenide (CIGS). The individual component layers of CIGS (e.g., copper layer, indium-gallium layer, selenium) can be electroplated layer by layer onto back-electrode 104. In some embodiments, the individual layers of the absorber layer are circumferentially deposited onto back-electrode 104 using sputtering. Regardless of whether the individual layers of absorber layer 106 are circumferentially deposited by sputtering or electroplating, or a combination thereof, in typical embodiments (e.g. where active layer 106 is CIGS), once component layers have been circumferentially deposited, the layers are rapidly heated up in a rapid thermal processing step so that they react with each other to form the absorber layer 106. In some embodiments, the selenium is not delivered by electroplating or sputtering. In such embodiments the selenium is delivered to the absorber layer 106 during a low pressure heating stage in the form of an elemental selenium gas, or hydrogen selenide gas during the low pressure heating stage. In some embodiments, copper-indium-gallium oxide is circumferentially deposited onto back-electrode 104 and then converted to copper-indium-gallium diselenide. In some embodiments, a vacuum process is used to deposit absorber layer 106. In some embodiments, a non-vacuum process is used to deposit absorber layer 106. In some embodiments, a room temperature process is used to deposit absorber layer 106. In still other embodiments, a high temperature process is used to deposit absorber layer 106. Those of skill in the art will appreciate that these processes are just exemplary and there are a wide range of other processes that can be used to deposit absorber layer 106. In some embodiments, absorber layer 106 is deposited using chemical vapor deposition.

Referring to FIG. 3F, window layer 108 is circumferentially disposed on absorber layer 106. In some embodiments, absorber layer 106 is circumferentially deposited onto absorber layer 108 using a chemical bath deposition process. For instance, in the case where window layer 108 is a buffer layer such as cadmium sulfide, the cadmium and sulfide can each be separately provided in solutions that, when reacted, results in cadmium sulfide precipitating out of the solution. In some embodiments, the window layer 108 is an n type buffer layer. In some embodiments, window layer 108 is sputtered onto absorber layer 106. In some embodiments, window layer 108 is evaporated onto absorber layer 106. In some embodiments, window layer 108 is circumferentially disposed onto absorber layer 106 using chemical vapor deposition.

Referring to FIGS. 3G and 3H, semiconductor junction 410 (e.g., layers 106 and 108) are patterned in order to create grooves 294. In some embodiments, grooves 294 run the full perimeter of semiconductor junction 410, thereby breaking the semiconductor junction 410 into discrete sections. In some embodiments, grooves 294 do not run the full perimeter of semiconductor junction 410. In fact, in some embodiments, each groove only extends a small percentage of the perimeter of semiconductor junction 410. In some embodiments, each photovoltaic cell 700 may have one, two, three, four or more, ten or more, or one hundred or more pockets arranged around the perimeter of semiconductor junction 410 instead of a given groove 294. In some embodiments, grooves 294 are scribed using a laser beam having a wavelength that is absorbed by semiconductor junction 410.

FIG. 3I depicts a schematic illustration of a set-up used to create groove 294, in accordance with the present application. After a primary laser beam pass, groove 294 is depicted with residual 354 scattered on its sides and bottom. One or more secondary laser beam passes further sweeps away, by evaporation/ablation, residual 354 that causes groove 294 to be electrically conductive. It is not necessary to fully remove all residual 354 from groove 294, so long as the groove is electrically isolating. In subsequent processing steps, groove 294 is to be filled with conductive material to provide a connection between back-electrode 104 and transparent conductor 110 from adjacent photovoltaic cells 700. Current does not flow directly from side 295-1 to side 295-2 once groove 294 is filled to form a via 280. In some embodiments, groove 294 is extended into back-electrode layer 104. Furthermore, no connection is formed between the back-electrode layer 104 and transparent conductor 110 in the same photovoltaic cell 700. Otherwise, the cell would short. As such, only one side of groove 294 needs to be completely electrically isolating. In the solar cell configuration illustrated in 3I, only side 295-2 needs to be electrically isolating. In other embodiments, solar cells may be configured such that side 295-1 needs to be electrically isolating.

Referring to FIG. 3J, transparent conductor 110 is circumferentially disposed on semiconductor junction 410. In some embodiments, transparent conductor 110 is circumferentially disposed onto back-electrode 104 by sputtering. In some embodiments, the sputtering is reactive sputtering. For example, in some embodiments a zinc target is used in the presence of oxygen gas to produce a transparent conductor 110 comprising zinc oxide. In another reactive sputtering example, an indium tin target is used in the presence of oxygen gas to produce a transparent conductor 110 comprising indium tin oxide. In another reactive sputtering example, a tin target is used in the presence of oxygen gas to produce a transparent conductor 110 comprising tin oxide. In general, any wide band gap conductive transparent material can be used as transparent conductor 110. As used herein, the term “transparent” means a material that is considered transparent in the wavelength range from about 300 nanometers to about 1500 nanometers. However, components that are not transparent across this full wavelength range can also serve as a transparent conductor 110, particularly if they have other properties such as high conductivity such that very thin layers of such materials can be used. In some embodiments, transparent conductor 110 is any transparent conductive oxide that is conductive and can be deposited by sputtering, either reactively or using ceramic targets.

In some embodiments, transparent conductor 110 is deposited using direct current (DC) diode sputtering, radio frequency (RF) diode sputtering, triode sputtering, DC magnetron sputtering or RF magnetron sputtering. In some embodiments, transparent conductor 110 is deposited using atomic layer deposition. In some embodiments, transparent conductor 110 is deposited using chemical vapor deposition.

Referring to 3K, transparent conductor 110 is patterned in order to create grooves 296. Grooves 296 run the full perimeter of transparent conductor 110 thereby breaking the transparent conductor 110 into discrete sections. The bottoms of grooves 296 expose underlying semiconductor junction 410. In some embodiments, a groove 298 is patterned at an end of solar cell unit 300 in order to connect the back-electrode 104 exposed by groove 296 to an electrode or other electronic circuitry. In some embodiments, grooves 296 are scribed using a laser beam having a wavelength that is absorbed by transparent conductor 110.

FIG. 3L provides a schematic illustration of a set-up in accordance with the present application. After a primary laser beam pass, groove 296 is depicted with residual 356 scattered on its sides and bottom. One or more secondary laser beam passes further sweep away residual 356, by evaporation/ablation, causing groove 296 to become electrically isolating. It is not necessary to fully remove all residual 356 material from the sides or bottom of groove 296 so long as the groove become electrically isolating. Because transparent conductor 110 is conductive, at least a portion of groove 296 must fully penetrate layer 110 to ensure electrical isolation.

Referring to FIG. 3M, optional antireflective coating 112 is circumferentially disposed on transparent conductor 110 using conventional deposition techniques. In some embodiments, solar cell units 300 are encased in a transparent tubular casing 310. More details on how elongated solar cells such as solar cell unit 300 can be encased in a transparent tubular case are described in U.S. patent application Ser. No. 11/378,847, filed Mar. 18, 2006, which is hereby incorporated by reference herein in its entirety. In some embodiments, an optional filler layer 330 is used to ensure that there are no pockets of air between the outer layers of solar cell unit 270 and the transparent tubular casing 310.

In some embodiments, counter-electrodes 420 are deposited on transparent conductor 110 using, for example, ink jet printing. Examples of conductive ink that can be used for such counter-electrodes include, but are not limited to silver loaded or nickel loaded conductive ink. In some embodiments epoxies as well as anisotropic conductive adhesives can be used to construct counter-electrodes 420. In typical embodiments such inks or epoxies are thermally cured in order to form counter-electrodes 420. In some embodiments, such counter-electrodes are not present in solar cell unit 300. In fact, in monolithic integrated designs, voltage across the length of the solar cell unit 300 is increased because of the presences of independent photovoltaic cell 700. Thus, current is decreased, thereby reducing the current requirements of individual photovoltaic cells 700. As a result, in many embodiments, there is no need for counter-electrodes 420.

In some embodiments, grooves 292, 294, and 296 are not concentric as illustrated in FIG. 3. Rather, in some embodiments, such grooves are spiraled down the tubular (long) axis of substrate 102. In some embodiments, optional filler layer 330 is circumferentially disposed onto transparent conductor 110 or antireflective layer 112. Depending on the embodiments, transparent tubular casing 310 is circumferentially fitted onto optional filler layer 330 (if present), or antireflective layer 112 (if present and if optional filler layer 330 is not present) or transparent conductor 110 (if optional filler layer 330 and antireflective layer 112 are not present). The methods and systems disclosed in the present application may be applied to create an electrically isolating groove (e.g., 292, 294, or 296) in any layer of a solar cell.

### 4.2 Laser and Laser-Induced Changes on Scribing Surfaces

Disclosed in this section are exemplary lasers and exemplary laser beam specifications that can be used to generate the primary laser beam pass (first pass) and the one or more secondary laser beam passes (collectively, the second pass) used by the apparatus, methods, and systems of the present application. A laser, known as a light amplification by stimulated emission of radiation, is an optical source that emits photons in a coherent beam. A laser is composed of an active laser medium or gain medium and a resonant optical cavity in addition to other optical devices. Laser medium or gain medium is the source that generates and emits a laser beam. A resonant optical cavity or any additional optical devices help to focus and manipulate the size and direction of emitted laser beam.

4.2.1 Exemplary Types of Lasers that can be Used in the Processing Steps of the Present Application

Depending on the state of the laser medium, the primary laser beam and one or more secondary laser beams may be generated by a gas, liquid, or solid laser. Gas lasers are further categorized into gas, gas-ion, chemical or excimer lasers, while solid lasers are further categorized to include solid state and semiconductor lasers. In some embodiments, the primary laser beam is generated by a first type of laser and the one or more secondary laser beam passes are generated by a second type of laser. In some embodiments, the primary laser beam pass and the one or more secondary laser beam passes are generated by the same type of laser.

Gas or gas-ion lasers. The Helium-neon laser (HeNe) emits light at 543 nm and 633 nm. Carbon dioxide lasers emit up to 100 kW at 9.6 μm and 10.6 μm. Argon-Ion lasers emit 458 nm, 488 nm or 514.5 nm light. Carbon monoxide lasers are typically cooled but can produce up to 500 kW. The Transverse Electrical discharge in gas at Atmospheric pressure (TEA) laser is an inexpensive gas laser producing UV Light at 337.1 nm. Metal ion lasers are gas lasers that generate deep ultraviolet wavelengths. Helium-Silver (HeAg) 224 nm and Neon-Copper (NeCu) 248 nm are two examples. These lasers typically have oscillation linewidths of less than 3 GHz (0.5 picometers).

Gas-ion lasers or vaporized ion lasers are capable of producing laser beams with wavelengths ranging from the ultraviolet, through the visible, into the near infrared portion of the spectrum. Ion lasers are compact for the amount of laser power they generate relative to other types of visible lasers. Commercially available gas-ion lasers include argon and krypton lasers. Argon-ion lasers produce high visible power levels and have multiple lasing wavelengths in the blue and green portion of the spectrum. Argon lasers are normally rated by the power level produced by the six simultaneously lasing wavelengths from 514.5 nm to 457.9 nm. The most prominent and most used wavelengths in the argon laser are the 514.5 nm green line and the 488.0 nm blue line. The wavelengths outside of the standard visible range, including a highly stable infrared line at 1090 nm, are available simply by changing mirrors. The UV wavelengths are produced from double-ionized transitions which require more than normal laser current levels. Krypton-ion lasers and argon lasers have similar construction, reliability and operating lifetimes. Under some conditions, krypton lasers can produce wavelengths over the full visible spectrum with lines in the red, yellow, green and blue. The 647.1 nm and 676.4 nm are the strongest. Krypton lasers are normally rated by the power level produced at 647.1 nm. This wavelength is often used because it can produce more red laser light than can be obtained from other types of lasers. Some of the argon and krypton lasers may be further refined to yield long-life ion lasers with the satisfactory optical stability, optical noise, wavelength range, power and beam versatility. Examples of commercially available argon and krypton lasers include but not limited to the LEXEL 85/95 SERIES from Lexel Product Division at Cambridge Lasers Laboratories (Fremont, Calif.).

Chemical lasers. Chemical lasers are powered by a chemical reaction, and can achieve high powers in continuous operation. For example, in the Hydrogen fluoride laser (2700-2900 nm) and the Deuterium fluoride laser (3800 nm) the reaction is the combination of hydrogen or deuterium gas with combustion products of ethylene in nitrogen trifluoride.

Excimer lasers. Excimer lasers produce ultraviolet light. Commercially available excimer lasers include the F2 (emitting at 157 nm), ArF (193 nm), KrCl (222 nm), KrF (248 nm), XeCl (308 nm), and XeF (351 nm).

Liquid Lasers. Liquid laser such as dye lasers use organic dyes as the gain media. The wide gain spectrum of available dyes allows these lasers to be highly tunable, or to produce very short-duration pulses (on the order of femtoseconds).

Solid-state lasers. Solid state laser materials are commonly made by doping a crystalline solid host with ions that provide the required energy states. An example is a laser made from ruby, or chromium-doped sapphire. Another common type is made from neodymium-doped yttrium aluminium garnet (YAG), known as Nd:YAG. Nd:YAG lasers can produce high powers in the infrared spectrum at 1064 nm. Nd:YAG lasers are commonly frequency doubled to produce 532 nm when a visible (green) coherent source is desired.

Ytterbium, holmium, thulium and erbium are other common dopants in solid state lasers. Ytterbium is used in crystals such as Yb:YAG, Yb:KGW, Yb:KYW, Yb:SYS, Yb:BOYS, Yb:CaF₂, typically operating around 1020-1050 nm. They are typically efficient and high powered due to a small quantum defect. Extremely high powers in ultrashort pulses can be achieved with Yb:YAG. Holmium-doped YAG crystals that emit at 2097 nm and form an efficient laser operating at infrared wavelengths strongly absorbed by water-bearing tissues. The Ho-YAG is usually operated in a pulsed mode, and passed through optical fiber surgical devices to resurface joints, remove rot from teeth, vaporize cancers, and pulverize kidney and gall stones. Titanium-doped sapphire (Ti:sapphire) produces a highly tunable infrared laser, used for spectroscopy.

Solid state lasers also include glass or optical fiber hosted lasers, for example, with erbium or ytterbium ions as the active species. These allow long gain regions, and can support suitiable output powers because the fiber's high surface area to volume ratio allows cooling, and its wave-guiding properties reduce thermal distortion of the beam.

Semiconductor lasers. Commercial laser diodes emit at wavelengths from 375 nm to 1800 nm, and wavelengths of over 3 μm have been demonstrated. Low power laser diodes are used in laser pointers, laser printers, and CD/DVD players. More powerful laser diodes are frequently used to optically pump other lasers with high efficiency. The highest power industrial laser diodes, with power up to 10 kW, are used in industry for cutting and welding. External-cavity semiconductor lasers have a semiconductor active medium in a larger cavity. These devices can generate high power outputs with good beam quality, wavelength-tunable narrow-linewidth radiation, or ultra short laser pulses.

Vertical cavity surface-emitting lasers (VCSELs) are semiconductor lasers whose emission direction is perpendicular to the surface of the wafer. VCSEL devices typically have a more circular output beam than conventional laser diodes, and potentially could be much cheaper to manufacture. VECSELs are external-cavity VCSELs. Quantum cascade lasers are semiconductor lasers that have an active transition between energy sub-bands of an electron in a structure containing several quantum wells.

In addition, a laser beam may be generated by an x-ray, infrared, ultraviolet, or free electron transfer laser.

4.2.2 Exemplary Laser Beams Specifications

Exemplary wavelengths. Because a laser beam is foremost a form of radiation generated by photons, characteristic properties of a laser beam include its wavelength or wavelengths. Laser light is typically near-monochromatic, e.g., consisting of a single wavelength or color, and emitted in a narrow focused beam. Depending on the laser media used, a laser beam used in the present application may have a wavelength with the ultraviolet range (e.g., 100 to 400 nm), the visible range (400-750 nm), and/or the infrared range (750 to 1.0×10⁶ nm). The following table provides commercially available examples of lasers can be used in the methods of the present application.

| | | |
|---|---|---|
| Laser Medium | Laser Type | Wavelength |

far infrared

| | | | |
|---|---|---|---|
| Er: Glass | Solid State | 1540 | nm |

near infrared

| | | | |
|---|---|---|---|
| Cr: Forsterite | Solid State | 1150–1350 | nm |
| HeNe | Gas | 1152 | nm |
| Argon | Gas-Ion | 1090 | nm |
| Nd: YAP | Solid State | 1080 | nm |
| Nd: YAG | Solid State | 1064 | nm |
| Nd: Glass | Solid State | 1060 | nm |
| Nd: YLF | Solid State | 1053 | nm |
| Nd: YLF | Solid State | 1047 | nm |
| InGaAs | Semiconductor | 980 | nm |
| Krypton | Gas-Ion | 799.3 | nm |
| Cr: LiSAF | Solid State | 780–1060 | nm |
| GaAs/GaAlAs | Semiconductor | 780–905 | nm |
| Krypton | Gas-Ion | 752.5 | nm |
| Ti: Sapphire | Solid State | 700–1000 | nm |

visible

| | | | |
|---|---|---|---|
| Ruby | Solid State | 694 | nm |
| Krypton | Gas-Ion | 676.4 | nm |
| Krypton | Gas-Ion | 647.1 | nm |
| InGaAlP | Semiconductor | 635–660 | nm |
| HeNe | Gas | 633 | nm |
| Ruby | Solid State | 628 | nm |
| HeNe | Gas | 612 | nm |
| HeNe | Gas | 594 | nm |
| Cu | Metal vapor | 578 | nm |
| Krypton | Gas-Ion | 568.2 | nm |
| HeNe | Gas | 543 | nm |
| DPSS | Semiconductor | 532 | nm |
| Krypton | Gas-Ion | 530.9 | nm |
| Argon | Gas-Ion | 514.5 | nm |
| Cu | Metal vapor | 511 | nm |
| Argon | Gas-Ion | 501.7 | nm |
| Argon | Gas-Ion | 496.5 | nm |
| Argon | Gas-Ion | 488.0 | nm |
| Argon | Gas-Ion | 476.5 | nm |
| Argon | Gas-Ion | 457.9 | nm |
| HeCd | Gas-Ion | 442 | nm |
| N2+ | Gas | 428 | nm |
| Krypton | Gas-Ion | 416 | nm |

near ultraviolet

| | | | |
|---|---|---|---|
| Argon | Gas-Ion | 364 | nm (UV-A) |
| XeF | Gas (excimer) | 351 | nm (UV-A) |
| N2 | Gas | 337 | nm (UV-A) |
| XeCl | Gas (excimer) | 308 | nm (UV-B) |

far ultraviolet

| | | | |
|---|---|---|---|
| Krypton SHG | Gas-Ion/BBO crystal | 284 | nm (UV-B) |
| Argon SHG | Gas-Ion/BBO crystal | 264 | nm (UV-C) |
| Argon SHG | Gas-Ion/BBO crystal | 257 | nm (UV-C) |
| Argon SHG | Gas-Ion/BBO crystal | 250 | nm (UV-C) |
| Argon SHG | Gas-Ion/BBO crystal | 248 | nm (UV-C) |
| KrF | Gas (excimer) | 248 | nm (UV-C) |
| Argon SHG | Gas-Ion/BBO crystal | 244 | nm (UV-C) |
| Argon SHG | Gas-Ion/BBO crystal | 238 | nm (UV-C) |
| Argon SHG | Gas-Ion/BBO crystal | 229 | nm (UV-C) |
| KrCl | Gas (excimer) | 222 | nm (UV-C) |
| ArF | Gas (excimer) | 193 | nm (UV-C) |

Exemplary pulse durations and fluence. Pulse duration of a laser beam is defined as the time during which the laser beam output power remains continuously above half its maximum value. A requirement in laser micromachining is that structural layers be patterned selectively. Damage to other layers is minimized. Fluence is the energy per unit of area that is delivered to a semiconductor substrate layer by a laser beam pulse. Typically, fluence is reported as Joules per centimeter squared (J/cm²). The precise value of the lower boundary of the acceptable fluence window range is determined by a number of variables, including the thickness of any layer in the one or more common layers in a solar cell, the composition of any layer in the one or more common layers in a solar cell, and the number of laser pulses used in the ablation process. Generally, an increase in the number of laser pulses used in the processes described in this application results in a decrease in the lower fluence boundary value necessary to melt a selected layer in the one or more common layers in a solar cell.

Patterning a thin film within these limitations may be achieved, for example, using an excimer laser with control of pulse duration. One- and two-axis laser schemes are devised to control the pulse duration, which is ruled by the saturation powers of the transitions in the absorber and in the gain medium. In one-axis lasers, adjustment of the pump and laser beam sizes in the active medium and in the absorber provides a means to control the pulse temporal shape and duration. Furthermore, a two-axis laser cavity supporting so-called forked-eigenstate operation permits free adjustment of the parts of the mode power that circulate in the gain medium and in the absorber. In some embodiments, using a diode-pumped Nd³⁺:YAG laser, a lengthening of the pulse duration up to 300 nanoseconds, up to 400 nanoseconds, up to 500 nanoseconds, up to 600 nanoseconds, up to 700 nanoseconds, or up to up to 800 nanoseconds, up to 500 microseconds, up to 500 milliseconds is obtained to provide the energy output necessary to melt and ablate a layer in the one or more common lasers in a solar cell. Shorter pulse durations are preferred for a given material so that laser energy does not propagate in the material during the pulse.

Laser beam sizes. The diameter of a Gaussian laser beam is conventionally measured at the 1/e² power point, e.g., the diameter of an aperture stop that will pass 86.5% of the total laser power at the plane of the output mirror. The size and shape of laser beams can be manipulated by series of mirrors and apertures. The beam divergence is usually given as the full angle divergence measured in the far field. Both parameters are related to the laser wavelength, mirror spacing and curvature of the mirrors. See, for example, Kogelnik and Li, 1966, “Laser Beams and Resonators,” Applied Optics 5: 1550, which is hereby incorporated by reference herein in its entirety. Diameter and divergence values for selected ion laser wavelengths are available lasers including but not limited to Lexel 85/95 series from Lexel Product Division at Cambridge Lasers Laboratories (Fremont, Calif.).

4.2.3. Laser-Related Changes in Material Properties

A laser beam is characterized by an instantaneous intensity (W/cm²) and an integrated intensity, or pulse energy (J/cm²). A laser beam interacts with the sample in one of two ways: some photons are reflected by the surface and some are absorbed in the bulk. Photons may be transmitted through the sample; these have no effect on the sample. The intensity reflected by the surface is

I_{reflected}=RI_{incident}

where R, the surface reflectivity, is a dimensionless number. The reflectivity depends on the material and phase and may also be a function of temperature, but it depends on these things only through the state of the surface element. The top element determines the reflectivity, and the deeper elements have no effect. Unlike reflectivity, absorption is affected by many layers near the surface. The intensity of the radiation within the sample is modeled by:

I(x)=(I_{incident}−I_{reflected})e^{-αx}

where α is the absorption coefficient (cm⁻¹) and x is the depth (cm).

Ablation threshold. Upon absorbing laser radiation, a layer in the one or more common layers may under go physical and morphological changes, including melting, evaporation, sublimation, and re-solidification. In order to create an electrically isolating groove, residual conductive material is removed. To evaporate or ablate a surface material, the incident laser it typically above the ablation threshold of the material. Ablation threshold, F₀, is the point at which the absorbed laser energy is sufficient to break the bonds between molecules of a material. Ablation threshold is determined by the chemical composition of the material. Laser beams used to ablate a material are selected based on characteristics such as fluence, wavelengths, pulse durations, intensities, etc.

Penetration depths. If the fluence, F, or energy density of the laser beam is above the ablation threshold, F₀, of the material, then a depth, I_{f}, of the material will be ablated by each pulse:

$${I}_{f} = \frac{1}{α} ln ( \frac{F}{{F}_{0}} )$$

where α is the absorption coefficient (cm⁻¹).

For thermal conductors such as metals, alloys and nitrides, ablation is dominated by thermal induced effects of the heat affected zone (HAZ). The depth of a HAZ, Lₜₕ, depends upon the material properties and the pulse duration of a laser beam:

$${L}_{th} = 2 \sqrt{\frac{k}{{C}_{p} ρ}} τ$$

where k is the thermal conductivity, Cₚ is the specific heat capacity and ρ is the density of the material, and τ is the pulse duration of the laser beam.

More detailed discussion on laser beams and their characteristics may be found in Svelto, 1998, “Principles of Lasers,” 4th ed. Springer and Csele, 2004, “Fundamentals of Light Sources and Lasers,” Wiley; and Kogelnik and Li, 1966, “Laser Beams and Resonators”, Applied Optics 5: 1550; each of which is hereby incorporated herein by reference in its entirety.

### 4.3 Exemplary Semiconductor Junctions

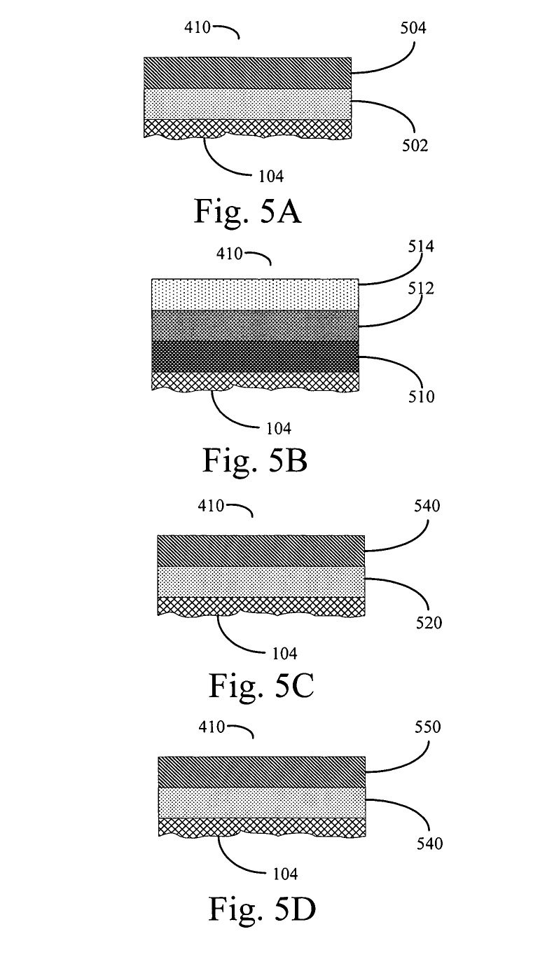

Referring to FIG. 5A, in one embodiment, semiconductor junction 410 is a heterojunction between an absorber layer 502, disposed on back-electrode 104, and a junction partner layer 504, disposed on absorber layer 502. Layers 502 and 504 are composed of different semiconductors with different band gaps and electron affinities such that junction partner layer 504 has a larger band gap than absorber layer 502. In some embodiments, absorber layer 502 is p-doped and junction partner layer 504 is n-doped. In such embodiments, transparent conductor 110 is n⁺-doped. In alternative embodiments, absorber layer 502 is n-doped and junction partner layer 504 is p-doped. In such embodiments, transparent conductor 110 is p⁺-doped. In some embodiments, the semiconductors listed in Pandey, Handbook of Semiconductor Electrodeposition, Marcel Dekker Inc., 1996, Appendix 5, which is hereby incorporated by reference herein in its entirety, are used to form semiconductor junction 410.

4.3.1 Thin-Film Semiconductor Junctions Based on Copper Indium Diselenide and Other Type I-III-VI Materials

Continuing to refer to FIG. 5A, in some embodiments, absorber layer 502 is a group I-III-VI₂ compound such as copper indium di-selenide (CuInSe₂; also known as CIS). In some embodiments, absorber layer 502 is a group I-III-VI₂ ternary compound selected from the group consisting of CdGeAs₂, ZnSnAs₂, CuInTe₂, AgInTe₂, CuInSe₂, CuGaTe₂, ZnGeAs₂, CdSnP₂, AgInSe₂, AgGaTe₂, CuInS₂, CdSiAs₂, ZnSnP₂, CdGeP₂, ZnSnAs₂, CuGaSe₂, AgGaSe₂, AgInS₂, ZnGeP₂, ZnSiAs₂, ZnSiP₂, CdSiP₂, or CuGaS₂ of either the p-type or the n-type when such compound is known to exist.

In some embodiments, junction partner layer 504 is CdS, ZnS, ZnSe, or CdZnS. In one embodiment, absorber layer 502 is p-type CIS and junction partner layer 504 is n⁻ type CdS, ZnS, ZnSe, or CdZnS. Such semiconductor junctions 410 are described in Chapter 6 of Bube, Photovoltaic Materials, 1998, Imperial College Press, London, which is hereby incorporated by reference in its entirety. Such semiconductor junctions 410 are described in Chapter 6 of Bube, Photovoltaic Materials, 1998, Imperial College Press, London, which is hereby incorporated by reference in its entirety.

In some embodiments, absorber layer 502 is copper-indium-gallium-diselenide (CIGS). Such a layer is also known as Cu(InGa)Se₂. In some embodiments, absorber layer 502 is copper-indium-gallium-diselenide (CIGS) and junction partner layer 504 is CdS, ZnS, ZnSe, or CdZnS. In some embodiments, absorber layer 502 is p-type CIGS and junction partner layer 504 is n-type CdS, ZnS, ZnSe, or CdZnS. Such semiconductor junctions 410 are described in Chapter 13 of Handbook of Photovoltaic Science and Engineering, 2003, Luque and Hegedus (eds.), Wiley & Sons, West Sussex, England, Chapter 12, which is hereby incorporated by reference in its entirety. In some embodiments, CIGS is deposited using techniques disclosed in Beck and Britt, Final Technical Report, January 2006, NREL/SR-520-39119; and Delahoy and Chen, August 2005, “Advanced CIGS Photovoltaic Technology,” subcontract report; Kapur et al., January 2005 subcontract report, NREL/SR-520-37284, “Lab to Large Scale Transition for Non-Vacuum Thin Film CIGS Solar Cells”; Simpson et al., October 2005 subcontract report, “Trajectory-Oriented and Fault-Tolerant-Based Intelligent Process Control for Flexible CIGS PV Module Manufacturing,” NREL/SR-520-38681; and Ramanathan et al., 31^{st} IEEE Photovoltaics Specialists Conference and Exhibition, Lake Buena Vista, Fla., Jan. 3-7, 2005, each of which is hereby incorporated by reference herein in its entirety.

In some embodiments CIGS absorber layer 502 is grown on a molybdenum back-electrode 104 by evaporation from elemental sources in accordance with a three stage process described in Ramanthan et al., 2003, “Properties of 19.2% Efficiency ZnO/CdS/CuInGaSe₂ Thin-film Solar Cells,” Progress in Photovoltaics: Research and Applications 11, 225, which is hereby incorporated by reference herein in its entirety. In some embodiments layer 504 is a ZnS(O,OH) buffer layer as described, for example, in Ramanathan et al., Conference Paper, “CIGS Thin-Film Solar Research at NREL: FY04 Results and Accomplishments,” NREL/CP-520-37020, January 2005, which is hereby incorporated by reference herein in its entirety.

In some embodiments, layer 502 is between 0.5 μm and 2.0 μm thick. In some embodiments, the composition ratio of Cu/(In+Ga) in layer 502 is between 0.7 and 0.95. In some embodiments, the composition ratio of Ga/(In+Ga) in layer 502 is between 0.2 and 0.4. In some embodiments the CIGS absorber has a <110> crystallographic orientation. In some embodiments the CIGS absorber has a <112> crystallographic orientation. In some embodiments the CIGS absorber is randomly oriented.

4.3.2 Semiconductor Junctions Based on Amorphous Silicon or Polycrystalline Silicon

In some embodiments, referring to FIG. 5B, semiconductor junction 410 comprises amorphous silicon. In some embodiments this is an n/n type heterojunction. For example, in some embodiments, layer 514 comprises SnO₂(Sb), layer 512 comprises undoped amorphous silicon, and layer 510 comprises n+ doped amorphous silicon.

In some embodiments, semiconductor junction 410 is a p-i-n type junction. For example, in some embodiments, layer 514 is p⁺ doped amorphous silicon, layer 512 is undoped amorphous silicon, and layer 510 is n⁺ amorphous silicon. Such semiconductor junctions 410 are described in Chapter 3 of Bube, Photovoltaic Materials, 1998, Imperial College Press, London, which is hereby incorporated by reference in its entirety.

In some embodiments of the present application, semiconductor junction 410 is based upon thin-film polycrystalline. Referring to FIG. 5B, in one example in accordance with such embodiments, layer 510 is a p-doped polycrystalline silicon, layer 512 is depleted polycrystalline silicon and layer 514 is n-doped polycrystalline silicon. Such semiconductor junctions are described in Green, Silicon Solar Cells: Advanced Principles & Practice, Centre for Photovoltaic Devices and Systems, University of New South Wales, Sydney, 1995; and Bube, Photovoltaic Materials, 1998, Imperial College Press, London, pp. 57-66, which is hereby incorporated by reference in its entirety.

In some embodiments of the present application, semiconductor junctions 410 based upon p-type microcrystalline Si:H and microcrystalline Si:C:H in an amorphous Si:H solar cell are used. Such semiconductor junctions are described in Bube, Photovoltaic Materials, 1998, Imperial College Press, London, pp. 66-67, and the references cited therein, which is hereby incorporated by reference in its entirety.

In some embodiments, of the present application, semiconductor junction 410 is a tandem junction. Tandem junctions are described in, for example,

Kim et al., 1989, “Lightweight (AlGaAs)GaAs/CuInSe2 tandem junction solar cells for space applications,” Aerospace and Electronic Systems Magazine, IEEE Volume 4, Issue 11, November 1989 Page(s):23-32; Deng, 2005, “Optimization of a-SiGe based triple, tandem and single-junction solar cells Photovoltaic Specialists Conference, 2005 Conference Record of the Thirty-first IEEE 3-7 Jan. 2005 Page(s): 1365-1370; Arya et al., 2000, Amorphous silicon based tandem junction thin-film technology: a manufacturing perspective,” Photovoltaic Specialists Conference, 2000. Conference Record of the Twenty-Eighth IEEE 15-22 Sep. 2000 Page(s):1433-1436; Hart, 1988, “High altitude current-voltage measurement of GaAs/Ge solar cells,” Photovoltaic Specialists Conference, 1988, Conference Record of the Twentieth IEEE 26-30 Sep. 1988 Page(s):764-765 vol. 1; Kim, 1988, “High efficiency GaAs/CuInSe2 tandem junction solar cells,” Photovoltaic Specialists Conference, 1988, Conference Record of the Twentieth IEEE 26-30 Sep. 1988 Page(s):457-461 vol. 1; Mitchell, 1988, “Single and tandem junction CuInSe2 cell and module technology,” Photovoltaic Specialists Conference, 1988., Conference Record of the Twentieth IEEE 26-30 Sep. 1988 Page(s):1384-1389 vol. 2; and Kim, 1989, “High specific power (AlGaAs)GaAs/CuInSe2 tandem junction solar cells for space applications,” Energy Conversion Engineering Conference, 1989, IECEC-89, Proceedings of the 24^{th} Intersociety 6-11 Aug. 1989 Page(s):779-784 vol. 2, each of which is hereby incorporated by reference herein in its entirety.

4.3.3 Semiconductor Junctions Based on Gallium Arsenide and Other Type III-V Materials

In some embodiments, semiconductor junctions 410 are based upon gallium arsenide (GaAs) or other III-V materials such as InP, AlSb, and CdTe. GaAs is a direct-band gap material having a band gap of 1.43 eV and can absorb 97% of AM1 radiation in a thickness of about two microns. Suitable type III-V junctions that can serve as semiconductor junctions 410 of the present application are described in Chapter 4 of Bube, Photovoltaic Materials, 1998, Imperial College Press, London, which is hereby incorporated by reference in its entirety.

Furthermore, in some embodiments semiconductor junction 410 is a hybrid multijunction solar cell such as a GaAs/Si mechanically stacked multijunction as described by Gee and Virshup, 1988, 20^{th} IEEE Photovoltaic Specialist Conference, IEEE Publishing, New York, p. 754, which is hereby incorporated by reference herein in its entirety, a GaAs/CuInSe₂ MSMJ four-terminal device, consisting of a GaAs thin film top cell and a ZnCdS/CuInSe₂ thin bottom cell described by Stanbery et al., 19^{th} IEEE Photovoltaic Specialist Conference, IEEE Publishing, New York, p. 280, and Kim et al., 20^{th} IEEE Photovoltaic Specialist Conference, IEEE Publishing, New York, p. 1487, each of which is hereby incorporated by reference herein in its entirety. Other hybrid multijunction solar cells are described in Bube, Photovoltaic Materials, 1998, Imperial College Press, London, pp. 131-132, which is hereby incorporated by reference herein in its entirety.

4.3.4 Semiconductor Junctions Based on Cadmium Telluride and Other Type II-VI Materials

In some embodiments, semiconductor junctions 410 are based upon II-VI compounds that can be prepared in either the n-type or the p-type form. Accordingly, in some embodiments, referring to FIG. 5C, semiconductor junction 410 is a p-n heterojunction in which layers 520 and 540 are any combination set forth in the following table or alloys thereof.

| Layer 520 | Layer 540 |
|---|---|
| n-CdSe | p-CdTe |
| n-ZnCdS | p-CdTe |
| n-ZnSSe | p-CdTe |
| p-ZnTe | n-CdSe |
| n-CdS | p-CdTe |
| n-CdS | p-ZnTe |
| p-ZnTe | n-CdTe |
| n-ZnSe | p-CdTe |
| n-ZnSe | p-ZnTe |
| n-ZnS | p-CdTe |
| n-ZnS | p-ZnTe |

### Methods for manufacturing semiconductor junctions 410 are based upon II-VI compounds are described in Chapter 4 of Bube, Photovoltaic Materials, 1998, Imperial College Press, London, which is hereby incorporated by reference in its entirety.

4.3.5 Semiconductor Junctions Based on Crystalline Silicon

While semiconductor junctions 410 that are made from thin film semiconductor films are preferred, the application is not so limited. In some embodiments semiconductor junctions 410 is based upon crystalline silicon. For example, referring to FIG. 5D, in some embodiments, semiconductor junction 410 comprises a layer of p-type crystalline silicon 540 and a layer of n-type crystalline silicon 550. Methods for manufacturing crystalline silicon semiconductor junctions 410 are described in Chapter 2 of Bube, Photovoltaic Materials, 1998, Imperial College Press, London, which is hereby incorporated by reference herein in its entirety.

### 4.4 Exemplary Dimensions

The present application encompasses solar cell assemblies having dimensions that fall within a broad range of dimensions. For example, the present application encompasses solar cell assemblies having a length l between 1 cm and 50,000 cm and a diameter w between 1 cm and 50,000 cm. In some embodiments, the solar cell assemblies have a length between 10 cm and 1,000 cm and a diameter between 10 cm and 1,000 cm. In some embodiments, the solar cell assemblies have a length between 40 cm and 500 cm and a width between 40 cm and 500 cm.

In some embodiments in accordance with the present application, a layer which will be scribed has a thickness of 0.1 micrometers or greater, 20 micrometers or greater, 200 micrometers or greater, 2000 micrometers or greater, 2.0×10⁴ micrometers or greater, 2.0×10⁵ micrometers or greater, or 2.0×10⁶ micrometers or greater. In some embodiments in accordance with the present application, a layer which will be scribed has a length of 0.2 centimeters or greater, 2 centimeters or greater, 20 centimeters or greater, 200 20 centimeters or greater, or 2000 centimeters or greater.

In embodiments where layers are circumferentially disposed on a cylindrical or rod shaped substrate (either hollowed or solid), the substrate has a diameter (or approximate diameter) of 0.2 centimeters or greater, 2 centimeters or greater, 20 centimeters or greater, or 200 centimeters or greater. In some embodiments, the tubular solar cells 300, for example, those depicted in FIG. 2B, have a diameter of between 1 micron and 1×10¹² microns, a diameter of greater than 1×10⁶ microns, a diameter of greater than 1×10⁷ microns, a diameter of greater than 1×10⁸ microns, a diameter of greater than 1×10⁹ microns, a diameter of greater than 1×10¹⁰ microns, a diameter of greater than 1×10¹¹ microns, a diameter of greater than 1×10¹² microns, or a diameter of greater than 1×10¹³ microns.

In some embodiments, the tubular solar cells, for example, those depicted in FIG. 2B, are arranged in parallel rows to form a planar assembly. The solar cells 300 may be electrically connected in series or parallel. In some embodiments, some solar cells 300 in the assembly are electrically arranged in series and some are electrically arranged in parallel. In some embodiments, some solar cells 300 are directly contacting other solar cells 300 in the assembly. In some embodiments, each solar cell 300 is spaced at least 1 micron, at least 2 microns, at least 3 microns, at least 4 microns, at least 5 microns, at least 100 microns, or at least 500 microns away from neighboring solar cells 300. In some such embodiments, solar cells 300 in the assembly are electrically isolated from neighboring solar cells in the assembly.

In some embodiments, the tubular solar cells 300 have a length of between 0.5 microns and 1×10¹⁸ microns, between 0.5 microns and 1×10¹⁷ microns, between 0.5 microns and 1×10¹⁶ microns, between 0.5 microns and 1×10¹⁵ microns, between 0.5 microns and 1×10¹⁴ microns, between 0.5 microns and 1×10¹³ microns, between 0.5 microns and 1×10¹² microns, between 0.5 microns and 1×10¹¹ microns, between 0.5 microns and 1×10¹⁰ microns, between 0.5 microns and 1×10⁹ microns, between 0.5 microns and 1×10⁸ microns, between 0.5 microns and 1×10⁷ microns, between 0.5 microns and 1×10⁶ microns, between 0.5 microns and 1×10⁵ microns, between 0.5 microns and 1×10⁴ microns, between 0.5 microns and 1×10³ microns, between 0.5 microns and 1×10² microns, between 0.5 microns and 10 microns, or between 0.5 microns and 1 micron. In some embodiments, each tubular solar cell 300 in an assembly has the same length. In some embodiments, each tubular solar cell 300 can have the same length or a different length than other tubular solar cells 300 in the assembly.

### 4.5 Exemplary Method

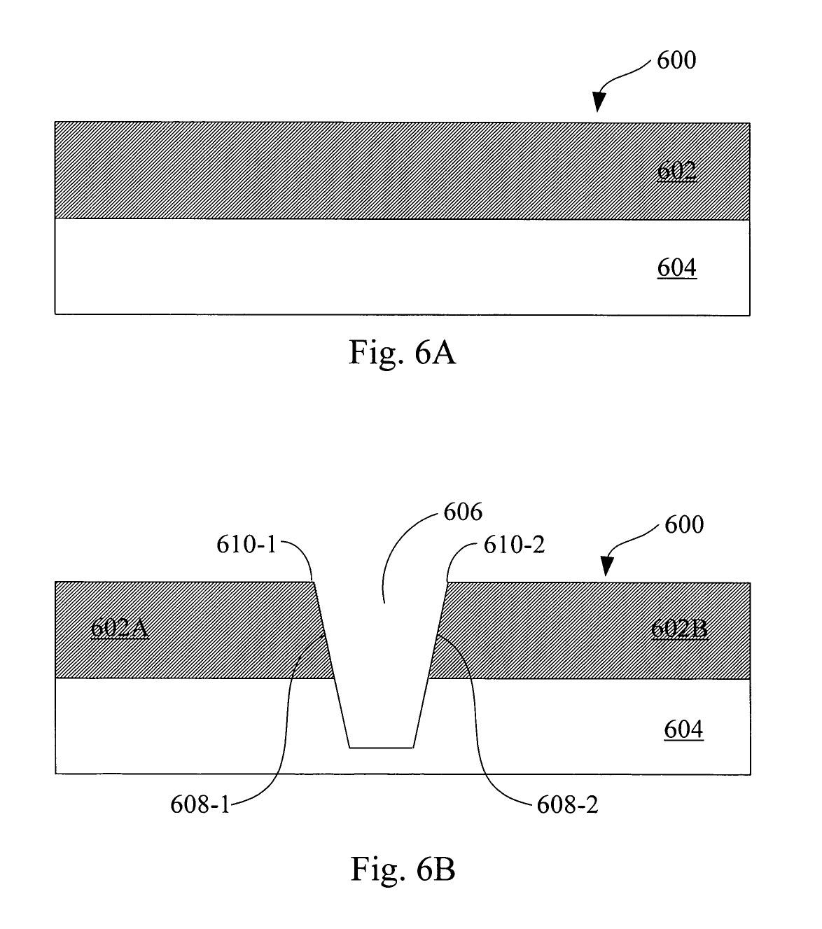

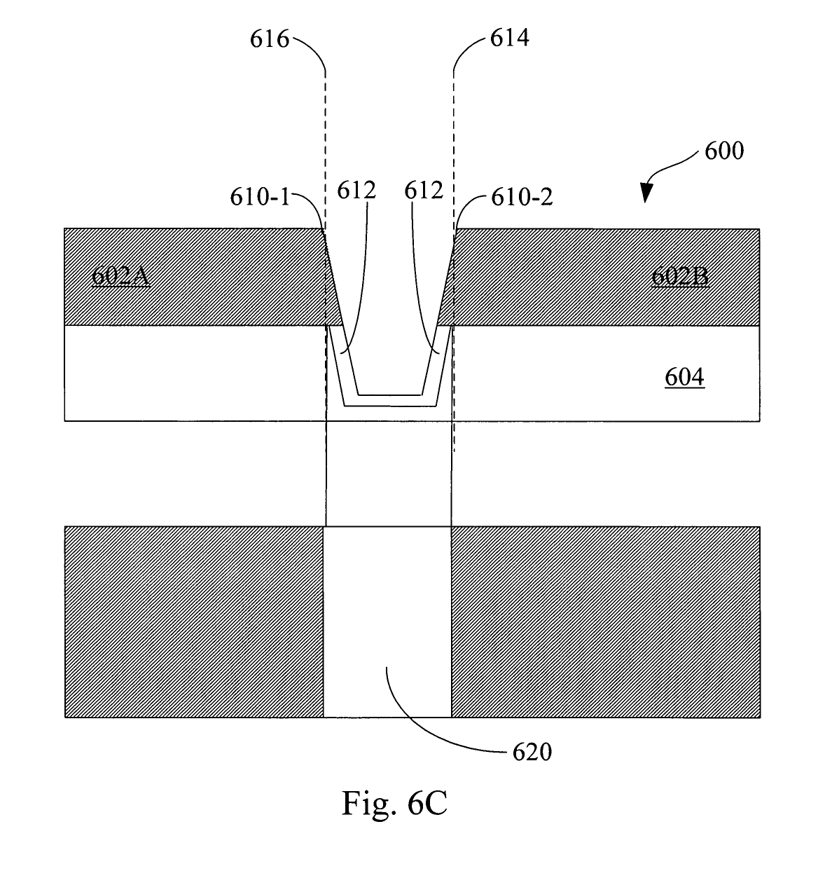

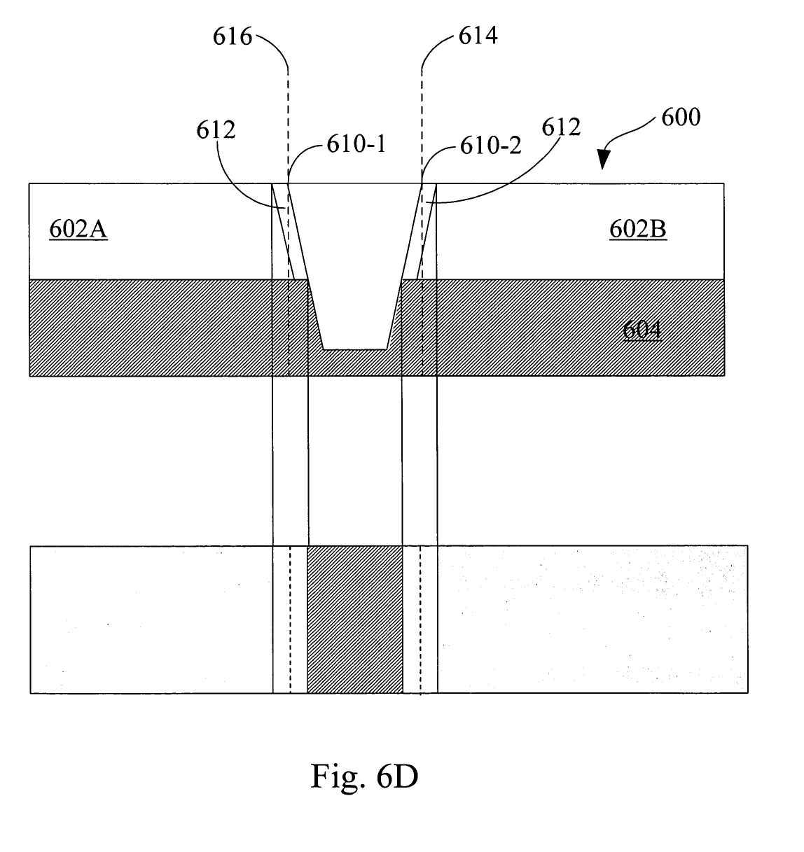

FIG. 6 illustrates an exemplary method of separating a first portion from a second portion of a first layer 602 in a solid volume 600, the solid volume 600 comprising at least the first layer 602 formed from a first substance and a second layer 604 formed from a second substance. As illustrated in FIG. 6A, the first layer 602 is disposed on the second layer 604. Although not shown, there can be any number of additional layers in solid volume 600. Furthermore, in some instances, solid volume 600 is overlayed on a substrate. In other instances, the lowest layer in the solid volume, for instance layer 604 in the solid volume 600 illustrated in FIG. 6A, is the substrate.

In the method, a first pass is made with a first laser beam over an area of solid volume 600. Examples of how such a first pass can be made are described in section 4.1.2, which the first pass is described as a primary laser beam pass. In some embodiments, the solid volume 600 is cylindrical or rod shaped and the area is a strip of area that traverses all or a portion of the circumference of the cylindrical or rod shaped volume. In some embodiments, the solid volume 600 is cylindrical or rod shaped and the area is a strip of area that traverses all or a portion of the length of the cylindrical or rod shaped volume. Referring to FIG. 6B, the first pass removes approximately all of the first layer within the area thereby creating a channel 606 in first layer 602. In some embodiments, the channel has a width of between 0.5 microns and 500 microns, between 1 micron and 400 microns, a width of less than 100 millimeters, a width of less than 10 millimeters, a width of less than 1 millimeter, or a width of greater then 50 microns. In some embodiments, channel 606 has a depth of between 0.5 microns and 10000 microns, between 0.5 microns and 1000 microns, between 0.5 microns and 100 microns, or between 0.5 microns and 10 microns. In some embodiments, channel 606 has a depth of greater than 5 microns, greater than 10 microns, greater than 100 microns, or greater than 1000 microns. As used herein, the term channel and groove are used interchangeably. Exemplary properties of the channel (groove) are described in Section 4.1.1, above.

As illustrated in FIG. 6B, channel 606 is characterized by a first edge 608-1 and a second edge 608-2. Edges 608 define the width of channel 606. There is no requirement that the width of channel 606 be absolutely uniform across the entire length of channel 606. Thus, in embodiments where the width of channel 606 is not uniform across the entire length of channel 606, the exemplary widths for channel 606 given above represent an average channel width. The channels of the present application have several useful purposes. For example they can serve to form the vias and other forms of grooves (channels) that are used to form a plurality of monolithically integrated solar cells on a single substrate as described, for example, in U.S. patent Ser. No. 11/378,835, which is hereby incorporated by reference herein in its entirety.

As illustrated in FIG. 6B, channel 606 separates the first portion 602A of first layer 602 from the second portion 602B of first layer 602 such that first portion 602A of first layer 602 is bounded by first edge 608-1 and second portion 602B of first layer 602 is bounded by second edge 608-2. Furthermore, the intersection of first edge 608-1 and the upper surface of first layer 602 is defined by a first lip 610-1. The intersection of second edge 610-2 and the upper surface of first layer 602 is defined by a second lip 610-2.

As a result of the first pass (e.g., primary laser beam pass), a heat-affected zone 612 is created within solid volume 600. Exemplary laser scribing processes that can be used to perform the first laser beam pass are described in Section 4.14 above. Exemplary laser types and laser specifications for such lasers that can be used to make the first laser beam pass are described in Section 4.2 above. As illustrated in FIG. 6C, in some embodiments, heat affected zone 612 arises in one or more layers beneath first layer 602, such as layer 604. This is particularly the case when layer 604 is a semiconductor junction such as CIGS. Exemplary semiconductor junctions are described in Section 4.3, above. In instances where a heat affected zone arises in a layer 604 made of CIGS, the CIGS becomes a conductive shunt between the conductive layers within solid object 600.

As illustrated in FIG. 6D, in some embodiments, heat affected zone 612 arises in first layer 602. This is particularly the case when layer 602 is a semiconductor junction such as CIGS. In some embodiments, layer 602 is any of the semiconductor junctions described in Section 4.3.

Referring to FIG. 6C, heat-affected zone 612 is disposed within a first area 620 approximately bounded between first lip 610-1 and second lip 610-2. It is possible for heat-affected zone 612 to exceed the area 620 on solid object 600 bounded by first lip 610-1 and second lip 610-2. Thus, using FIG. 6C to illustrate, the right hand portion of heat affected zone 612 may penetrate to the right of line 614 defined by lip 610-2. Further, the left hand portion of heat affected zone 612 may penetrate to the left of line 616 defined by lip 610-1.

In FIG. 6D, heat-affected zone 612 is disposed within a first area approximately bounded between first lip 610-1 and second lip 610-2. It is possible for heat-affected zone 612 to exceed the first area on solid object 600 bounded by first lip 610-1 and second lip 610-2. Thus, using FIG. 6D to illustrate, the right hand portion of heat affected zone 612 may penetrate to the right of line 614 defined by lip 610-2. Further, the left hand portion of heat affected zone 612 may penetrate to the left of line 616 defined by lip 610-1.

In the method, a second pass is made with a second laser beam over the first area. The second pass removes a portion of heat-affected zone 612. Exemplary details of such a second pass are described in Section 4.1.2 where the second pass is referred to, in that section, as one or more secondary laser beam passes. In some embodiments, the second pass comprises a plurality of laser beam passes. In some embodiments, the first laser beam and the second laser beam are generated by a common laser apparatus, such as any of the laser beams described in Section 4.2. In some embodiments, the first laser beam and the second laser beam are each generated by a different laser apparatus. In some embodiments, the first laser beam or the second laser beam is generated by a pulsed laser. In some embodiments, the pulsed laser has a pulse frequency in the range of 0.1 kilohertz (kHz) to 1,000 kHz during a portion of the first pass or a portion of the second pass. In some embodiments, a dose of radiant energy in a range from 0.01 Joules per square centimeters (J/cm²) to 50.0 J/cm² is delivered during a portion of the first pass or a portion of the second pass.

In some embodiments, first layer 602 is a conductive layer. In some embodiments, this conductive layer comprises aluminum, molybdenum, tungsten, vanadium, rhodium, niobium, chromium, tantalum, titanium, steel, nickel, platinum, silver, gold, an alloy thereof, or any combination thereof. In some embodiments, this conductive layer comprises indium tin oxide, titanium nitride, tin oxide, fluorine doped tin oxide, doped zinc oxide, aluminum doped zinc oxide, gallium doped zinc oxide, boron dope zinc oxide indium-zinc oxide, a metal-carbon black-filled oxide, a graphite-carbon black-filled oxide, a carbon black-carbon black-filled oxide, a superconductive carbon black-filled oxide, an epoxy, a conductive glass, or a conductive plastic.

In some embodiments, layer 604 is a semiconductor layer. For instance, in some embodiments, second layer is a semiconductor junction. Exemplary semiconductor junctions are described in Section 4.3. In some embodiments, he semiconductor junction comprises an absorber layer and a junction partner layer, where the junction partner layer is disposed on the absorber layer. In some embodiments, the absorber layer is copper-indium-gallium-diselenide and the junction partner layer is In₂Se₃, In₂S₃, ZnS, ZnSe, CdInS, CdZnS, ZnIn₂Se₄, Zn₁₋ₓMgₓO, CdS, SnO₂, ZnO, ZrO₂, doped ZnO, or a combination thereof.

In some embodiments, layer 602 is a semiconductor layer. In some embodiments, layer 602 is a semiconductor junction, such as any of the semiconductor junctions described in Section 4.3. In some embodiments, the semiconductor junction comprises an absorber layer and a junction partner layer, where the junction partner layer is disposed on the absorber layer. In some embodiments, the absorber layer is copper-indium-gallium-diselenide and the junction partner layer is In₂Se₃, In₂S₃, ZnS, ZnSe, CdInS, CdZnS, ZnIn₂Se₄, Zn₁₋ₓMgₓO, CdS, SnO₂, ZnO, ZrO₂, doped ZnO, or a combination thereof.

In some embodiments, the heat-affected zone is created in a semiconductor layer. In some embodiments, the heat-affected zone is created in a semiconductor junction. In some embodiments, solid volume 600 is disposed on a substrate. This substrate can be, for example, cylindrical (with a solid core, a hollow core, or partly hollow and partly solid core), planar, or approximately planar.

### 5. REFERENCES CITED

All references cited herein are incorporated herein by reference in their entirety and for all purposes to the same extent as if each individual publication or patent or patent application was specifically and individually indicated to be incorporated by reference in its entirety for all purposes.

Many modifications and variations of this application can be made without departing from its spirit and scope, as will be apparent to those skilled in the art. The specific embodiments described herein are offered by way of example only, and the application is to be limited only by the terms of the appended claims, along with the full scope of equivalents to which such claims are entitled.

We claim:

1. A method for forming a photovoltaic cell from a common layer on a substrate, the method comprising:
making a first pass with a first laser beam over an area on the common layer, the first pass forming a groove in the common layer, the first pass forming within the common layer a first edge and a second edge, the first edge separated from the second edge by the groove, the groove providing a first level of electrical isolation between the first edge and the second edge; and
making a second pass with a second laser beam over approximately the same area on the common layer, the second pass providing a second level of electrical isolation between the first edge and the second edge, the second level of electrical isolation being greater than the first level of electrical isolation.

2. The method of claim 1, wherein the second pass comprises a plurality of laser beam passes.

3. The method of claim 1, wherein the first laser beam and the second laser beam are generated by a common laser apparatus.

4. The method of claim 1, wherein the first laser beam and the second laser beam are each generated by a different laser apparatus.

5. The method of claim 1, wherein the first laser beam or the second laser beam is generated by a pulsed laser.

6. The method of claim 5, wherein the pulsed laser has a pulse frequency in the range of 0.1 kilohertz (kHz) to 1,000 kHz during a portion of the first pass or a portion of the second pass.

7. The method of claim 1, wherein a dose of radiant energy in a range from 0.01 Joules per square centimeters (J/cm²) to 50.0 J/cm² is delivered during a portion of the first pass or a portion of the second pass.

8. The method of claim 1, wherein the common layer is a conductive layer.

9. The method of claim 8, wherein the conductive layer comprises aluminum, molybdenum, tungsten, vanadium, rhodium, niobium, chromium, tantalum, titanium, steel, nickel, platinum, silver, gold, an alloy thereof, or any combination thereof.

10. The method of claim 9, wherein the conductive layer comprises indium tin oxide, titanium nitride, tin oxide, fluorine doped tin oxide, doped zinc oxide, aluminum doped zinc oxide, gallium doped zinc oxide, boron dope zinc oxide indium-zinc oxide, a metal-carbon black-filled oxide, a graphite-carbon black-filled oxide, a carbon black-carbon black-filled oxide, a superconductive carbon black-filled oxide, an epoxy, a conductive glass, or a conductive plastic.

11. The method of claim 1, wherein the substrate is cylindrical shaped.

12. The method of claim 11, wherein the substrate has a hollow core.

13. The method of claim 1, wherein the substrate is planar.

14. A method of separating a first portion from a second portion of a first layer in a solid volume, the solid volume comprising the first layer formed from a first substance and a second layer formed from a second substance, the first layer disposed on the second layer, the method comprising:
(A) making a first pass with a first laser beam over an area of the solid volume, the first pass:
(i) removing approximately all of the first layer within the area;
(ii) based on the step of removing, creating a channel in the first layer, the channel characterized by a first edge and a second edge, the first portion of the first layer bounded by the first edge and the second portion of the first layer bounded by the second edge, the intersection of the first edge and the first layer defined by a first lip and the intersection of the second edge and the first layer defined by a second lip; and
(iii) creating a heat-affected zone within the solid volume, the heat-affected zone disposed within a first area approximately bounded between the first lip and the second lip; and
(B) making a second pass with a second laser beam over the first area, the second pass removing a portion of the heat-affected zone.

15. The method of claim 14, wherein the second pass comprises a plurality of laser beam passes.

16. The method of claim 14, wherein the first laser beam and the second laser beam are generated by a common laser apparatus.

17. The method of claim 14, wherein the first laser beam and the second laser beam are each generated by a different laser apparatus.

18. The method of claim 14, wherein the first laser beam or the second laser beam is generated by a pulsed laser.

19. The method of claim 18, wherein the pulsed laser has a pulse frequency in the range of 0.1 kilohertz (kHz) to 1,000 kHz during a portion of the first pass or a portion of the second pass.

20. The method of claim 14, wherein a dose of radiant energy in a range from 0.01 Joules per square centimeters (J/cm²) to 50.0 J/cm² is delivered during a portion of the first pass or a portion of the second pass.

21. The method of claim 14, wherein the first layer is a conductive layer.

22. The method of claim 21, wherein the conductive layer comprises aluminum, molybdenum, tungsten, vanadium, rhodium, niobium, chromium, tantalum, titanium, steel, nickel, platinum, silver, gold, an alloy thereof, or any combination thereof.

23. The method of claim 21, wherein the conductive layer comprises indium tin oxide, titanium nitride, tin oxide, fluorine doped tin oxide, doped zinc oxide, aluminum doped zinc oxide, gallium doped zinc oxide, boron dope zinc oxide indium-zinc oxide, a metal-carbon black-filled oxide, a graphite-carbon black-filled oxide, a carbon black-carbon black-filled oxide, a superconductive carbon black-filled oxide, an epoxy, a conductive glass, or a conductive plastic.

24. The method of claim 14, wherein the second layer is a semiconductor layer.

25. The method of claim 14, wherein the second layer is a semiconductor junction.

26. The method of claim 25, wherein the semiconductor junction comprises an absorber layer and a junction partner layer, wherein the junction partner layer is disposed on the absorber layer.

27. The method of claim 26, wherein the absorber layer is copper-indium-gallium-diselenide and the junction partner layer is In₂Se₃, In₂S₃, ZnS, ZnSe, CdInS, CdZnS, ZnIn₂Se₄, Zn₁₋ₓMgₓO, CdS, SnO₂, ZnO, ZrO₂, doped ZnO, or a combination thereof.

28. The method of claim 14, wherein the first layer is a semiconductor layer.

29. The method of claim 14, wherein the first layer is a semiconductor junction.

30. The method of claim 29, wherein the semiconductor junction comprises an absorber layer and a junction partner layer, wherein the junction partner layer is disposed on the absorber layer.

31. The method of claim 30, wherein the absorber layer is copper-indium-gallium-diselenide and the junction partner layer is In₂Se₃, In₂S₃, ZnS, ZnSe, CdInS, CdZnS, ZnIn₂Se₄, Zn₁₋ₓMgₓO, CdS, SnO₂, ZnO, ZrO₂, doped ZnO, or a combination thereof.

32. The method of claim 14, wherein the heat-affected zone is created in a semiconductor layer.

33. The method of claim 14, wherein the heat-affected zone is created in a semiconductor junction.

34. The method of claim 14, wherein the solid volume is disposed on a substrate.

35. The method of claim 34, wherein the substrate is cylindrical.

36. The method of claim 34, wherein the substrate has a hollow core.

37. The method of claim 34, wherein the substrate is planar.

38. A solar cell unit comprising:
a substrate; and
a plurality of solar cells linearly arranged on the substrate, the plurality of solar cells comprising a first solar cell and a second solar cell, each solar cell in the plurality of solar cells comprising:
a plurality of layers, the plurality of layers comprising:
a back-electrode layer disposed on the substrate;
a semiconductor junction layer disposed on the back-electrode; and
a transparent conductor layer disposed on the semiconductor junction, wherein
the transparent conductor layer of the first solar cell in the plurality of solar cells is in serial electrical communication with the back-electrode layer of the second solar cell in the plurality of solar cells; and
a first layer from amongst: a) the back-electrode layer, b) the semiconductor junction layer, or c) the transparent conductor layer of a solar cell in said plurality of solar cells is patterned by:
i) making a first pass with a first laser beam over an area on the first layer, the first pass forming a groove in the first layer, the first pass forming within the first layer a first edge and a second edge, the first edge separated from the second edge by the groove, the groove providing a first level of electrical isolation between the first edge and the second edge; and
making a second pass with a second laser beam over approximately the same area on the first layer, the second pass providing a second level of electrical isolation between the first edge and the second edge, the second level of electrical isolation being greater than the first level of electrical isolation.

39. The solar cell unit of claim 38, wherein the back-electrode of a solar cell in said plurality of solar cells comprises aluminum, molybdenum, tungsten, vanadium, rhodium, niobium, chromium, tantalum, titanium, steel, nickel, platinum, silver, gold, an alloy thereof, or any combination thereof.

40. The solar cell unit of claim 38, wherein the back-electrode of a solar cell in the plurality of solar cells comprises indium tin oxide, titanium nitride, tin oxide, fluorine doped tin oxide, doped zinc oxide, aluminum doped zinc oxide, gallium doped zinc oxide, boron dope zinc oxide indium-zinc oxide, a metal-carbon black-filled oxide, a graphite-carbon black-filled oxide, a carbon black-carbon black-filled oxide, a superconductive carbon black-filled oxide, an epoxy, a conductive glass, or a conductive plastic.

41. The solar cell unit of claim 38, wherein the semiconductor junction of a solar cell in the plurality of solar cells comprises a homojunction, a heterojunction, a heteroface junction, a buried homojunction, a p-i-n junction, or a tandem junction.

42. The solar cell unit of claim 38, wherein the semiconductor junction of a solar cell in the plurality of solar cells comprises an absorber layer and a junction partner layer, wherein the junction partner layer is circumferentially disposed on the absorber layer.

43. The solar cell unit of claim 42, wherein the absorber layer is copper-indium-gallium-diselenide and the junction partner layer is In₂Se₃, In₂S₃, ZnS, ZnSe, CdInS, CdZnS, ZnIn₂Se₄, Zn₁₋ₓMgₓO, CdS, SnO₂, ZnO, ZrO₂, doped ZnO, or a combination thereof.

44. The solar cell unit of claim 38, wherein the transparent conductor layer of a solar cell in the plurality of solar cells comprises carbon nanotubes, tin oxide, fluorine doped tin oxide, indium-tin oxide (ITO), doped zinc oxide, aluminum doped zinc oxide, gallium doped zinc oxide, boron dope zinc oxide indium-zinc oxide or any combination thereof.

45. The solar cell unit of claim 44, wherein the substrate is cylindrical.

46. The solar cell unit of claim 44, wherein the substrate has a hollow core.

47. The solar cell unit of claim 44, wherein the substrate is planar.
